(19) United States
(12) Patent Application Publication
(10) Pub. No.: US 2024/0136352 A1
(43) Pub. Date: Apr. 25, 2024

(54) SEMICONDUCTOR DEVICE AND METHOD OF MANUFACTURING THE SAME

(71) Applicant: RENESAS ELECTRONICS CORPORATION, Tokyo (JP)

(72) Inventors: Natsumi IKEDA, Tokyo (JP); Tohru KAWAI, Tokyo (JP)

(21) Appl. No.: 18/452,834

(22) Filed: Aug. 20, 2023

(30) Foreign Application Priority Data
Oct. 24, 2022 (JP) 2022-170855

(51) Int. Cl. H01L 27/06; H01L 21/265; H01L 21/266; H01L 21/8234; H01L 29/08; H01L 29/423; H01L 29/66; H01L 29/78

(52) U.S. Cl. CPC H01L 27/0629; H01L 21/26513; H01L 21/26586; H01L 21/266; H01L 21/823462; H01L 21/823475; H01L 28/20; H01L 29/0847; H01L 29/42364; H01L 29/66492; H01L 29/7833

(57) ABSTRACT

A semiconductor device including an oscillation circuit includes a MISFET having a halo region formed on a semiconductor substrate and a plurality of MISFETs having no halo regions formed on the semiconductor substrate. Gate electrodes of the plurality of MISFETs having no halo regions are electrically connected to each other. The plurality of MISFETs having no halo regions is used in a pair transistor included in the oscillation circuit.

### CROSS-REFERENCE TO RELATED APPLICATIONS

The disclosure of Japanese Patent Application No. 2022-170855 filed on Oct. 25, 2022, including the specification, drawings and abstract is incorporated herein by reference in its entirety.

### BACKGROUND

The present disclosure relates to a semiconductor device and a manufacturing method of the same, and can be suitably used, for example, in the semiconductor device including an oscillation circuit and the manufacturing method of the same.

There are disclosed techniques listed below.
[Patent Document 1] Japanese Unexamined Patent Application Publication No. Hei 09-45906
[Patent Document 2] Japanese Unexamined Patent Application Publication No. 2019-9345
Patent Document 1 discloses a technique of forming a pocket region after forming a source region and a drain region.
Patent Document 2 discloses a technique related to a semiconductor device including an oscillation circuit.

### SUMMARY

Improving a performance of the semiconductor device including the oscillation circuit is desirable.

Other objects and novel features will become apparent from the description of this specification and the accompanying drawings.

According to one embodiment, a semiconductor device including an oscillation circuit includes a semiconductor substrate, a plurality of first MISFETs formed in the semiconductor substrate, and a plurality of second MISFETs formed in the semiconductor substrate. Each of the plurality of first MISFETs includes a halo region, and each of the plurality of second MISFETs includes no halo region. The plurality of second MISFETs is used as a pair transistor included in the oscillation circuit.

According to one embodiment, the performance of the semiconductor device including the oscillation circuit can be improved.

### BRIEF DESCRIPTION OF THE DRAWINGS

FIG. 1 is a plan view of a main portion of a semiconductor device according to one embodiment.

FIG. 2 is a plan view of the main portion of the semiconductor device according to one embodiment.

FIG. 3 is a cross-sectional view of the main portion of the semiconductor device according to one embodiment.

FIG. 4 is a plan view of the main portion of the semiconductor device according to one embodiment.

FIG. 5 is a cross-sectional view of the main portion of the semiconductor device according to one embodiment.

FIG. 6 is a cross-sectional view of the main portion of the semiconductor device according to one embodiment.

FIG. 7 is a plan view of a main portion of a semiconductor device according to a modified example.

FIG. 8 is a cross-sectional view of the main portion in a manufacturing step of the semiconductor device according to one embodiment.

FIG. 9 is a cross-sectional view of the main portion in the same manufacturing step of the semiconductor device as in FIG. 8.

FIG. 10 is a cross-sectional view of the main portion in the manufacturing step of the semiconductor device following FIG. 8.

FIG. 11 is a cross-sectional view of the main portion in the same manufacturing step of the semiconductor device as in FIG. 10.

FIG. 12 is a cross-sectional view of the main portion in the manufacturing step of the semiconductor device following FIG. 10.

FIG. 13 is a cross-sectional view of the main portion in the same manufacturing step of the semiconductor device as in FIG. 12.

FIG. 14 is a cross-sectional view of the main portion in the manufacturing step of the semiconductor device following FIG. 12.

FIG. 15 is a cross-sectional view of the main portion in the same manufacturing step of the semiconductor device as in FIG. 14.

FIG. 16 is a cross-sectional view of the main portion in the manufacturing step of the semiconductor device following FIG. 14.

FIG. 17 is a cross-sectional view of the main portion in the same manufacturing step of the semiconductor device as in FIG. 16.

FIG. 18 is a cross-sectional view of the main portion in the manufacturing step of the semiconductor device following FIG. 16.

FIG. 19 is a cross-sectional view of the main portion in the same manufacturing step of the semiconductor device as in FIG. 18.

FIG. 20 is a cross-sectional view of the main portion in the manufacturing step of the semiconductor device following FIG. 18.

FIG. 21 is a cross-sectional view of the main portion in the same manufacturing step of the semiconductor device as in FIG. 20.

FIG. 22 is a cross-sectional view of a main portion in a manufacturing step of a semiconductor device according to a first modified example.

FIG. 23 is a cross-sectional view of the main portion in the manufacturing step of the semiconductor device following FIG. 22.

FIG. 24 is a cross-sectional view of the main portion in the same manufacturing step of the semiconductor device as in FIG. 23.

FIG. 25 is a cross-sectional view of the main portion in the same manufacturing step of the semiconductor device as in FIG. 23.

FIG. 26 is a cross-sectional view of the main portion in the manufacturing step of the semiconductor device following FIG. 23.

FIG. 27 is a cross-sectional view of the main portion in the same manufacturing step of the semiconductor device as in FIG. 26.

FIG. 28 is a cross-sectional view of the main portion in the same manufacturing step of the semiconductor device as in FIG. 26.

FIG. 29 is a cross-sectional view of a main portion in a manufacturing step of a semiconductor device according to a second modified example.

FIG. 30 is a cross-sectional view of the main portion in the same manufacturing step of the semiconductor device as in FIG. 29.

FIG. 31 is a cross-sectional view of the main portion in the manufacturing step of the semiconductor device following FIG. 29.

FIG. 32 is a cross-sectional view of the main portion in the same manufacturing step of the semiconductor device as in FIG. 31.

FIG. 33 is a cross-sectional view of the main portion in the manufacturing step of the semiconductor device following FIG. 31.

FIG. 34 is a cross-sectional view of the main portion in the same manufacturing step of the semiconductor device as FIG. 33.

FIG. 35 is a cross-sectional view of the main portion in the manufacturing step of the semiconductor device following FIG. 33.

FIG. 36 is a cross-sectional view of the main portion in the same manufacturing step of the semiconductor device as in FIG. 35.

FIG. 37 is a circuit diagram showing a part of an oscillation circuit.

FIG. 38 is a circuit block diagram of the semiconductor device according to one embodiment.

FIG. 39 is a cross-sectional view of the main portion of the semiconductor device according to one embodiment.

FIG. 40 is a cross-sectional view of the main portion of the semiconductor device according to one embodiment.

FIG. 41 is a step flowchart showing manufacturing steps of the semiconductor device.

FIG. 42 is a circuit diagram of the pair transistor.

FIG. 43 is a circuit diagram of the pair transistor.

FIG. 44 is a circuit diagram of the pair transistor.

FIG. 45 is a circuit diagram of the pair transistor.

FIG. 46 is a plan view showing an exemplary layout of the pair transistor.

FIG. 47 is a plan view showing an exemplary layout of the pair transistor.

FIG. 48 is a plan view showing an exemplary layout of the pair transistor.

FIG. 49 is a cross-sectional view of the main portion of the semiconductor device when applying the layout in FIG. 47.

FIG. 50 is a cross-sectional view of the main portion of the semiconductor device when applying the layout in FIG. 47.

FIG. 51 is a plan view of the main portion of the semiconductor device according to one embodiment.

FIG. 52 is a cross-sectional view of the main portion of the semiconductor device according to one embodiment.

FIG. 53 is a plan view of the main portion of the semiconductor device according to one embodiment.

FIG. 54 is a cross-sectional view of the main portion of the semiconductor device according to one embodiment.

### DETAILED DESCRIPTION

In the following embodiments, when required for convenience, the description will be made by dividing into a plurality of sections or embodiments, but except when specifically stated, they are not independent of each other, and one is related to the modified example, detail, supplementary description, or the like of part or all of the other. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle. Furthermore, in the following embodiments, it is needless to say that the constituent elements (including element steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above numerical values and ranges.

Hereinafter, embodiments will be described in detail based on the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In the drawings used in the embodiments, hatching may be omitted even in the case of cross-sectional view in order to make the drawings easier to see. Also, even in the case of a plan view, hatching may be used to make the drawing easier to see.

### Structure of Semiconductor Device

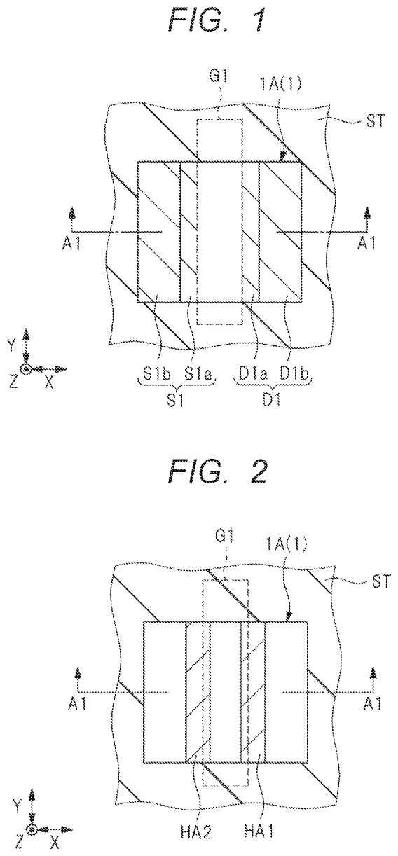

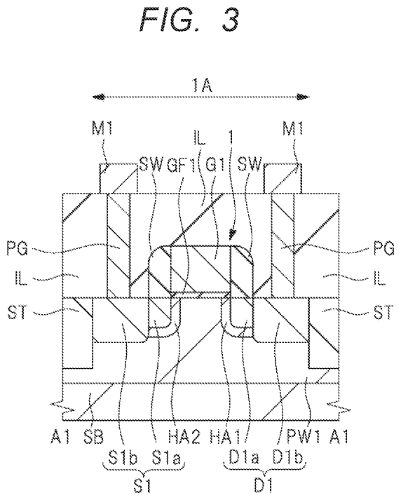

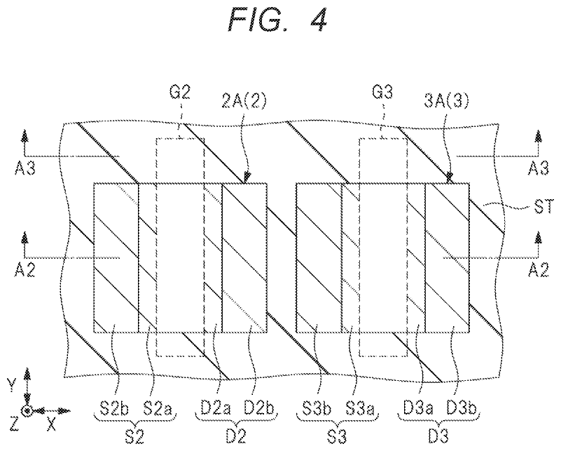

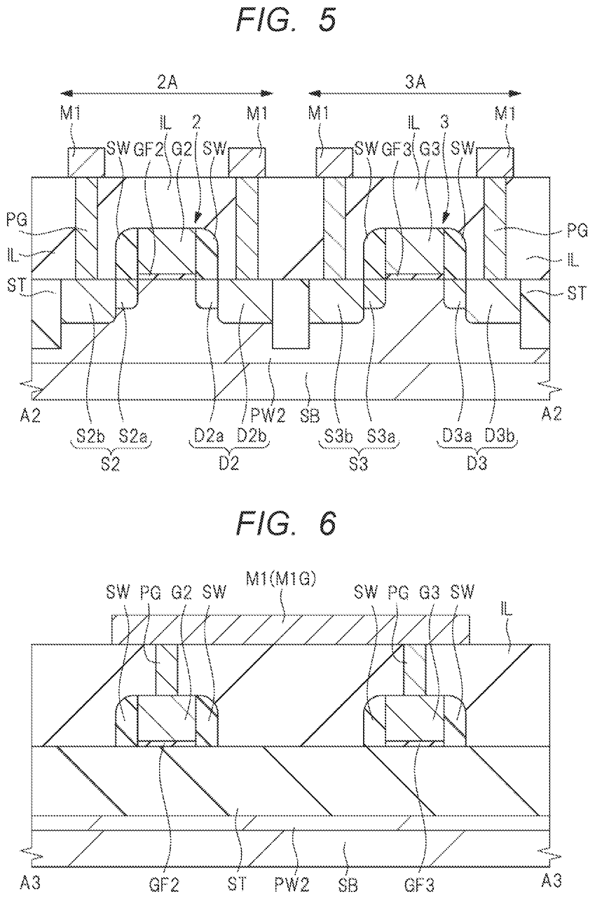

FIG. 1 and FIG. 2 are plan views of the main portion of the semiconductor device in the present embodiment, FIG. 3 is a plan view of the main portion of the semiconductor device in the present embodiment, and the cross-sectional view along A1-A1 line in FIG. 1 and FIG. 2 corresponds to FIG. 3. FIG. 4 is a plan view of the main portion of the semiconductor device in the present embodiment, FIG. 5 and FIG. 6 are cross-sectional views of the main portion of the semiconductor device in the present embodiment, the cross-sectional view along A2-A2 line in FIG. 4 corresponds to FIG. 5, and the cross-sectional view at A3-A3 line in FIG. 4 corresponds to FIG. 6.

Note that an X-direction, a Y-direction, and a Z-direction shown in FIGS. 1, 2, 4, and the like are orthogonal to each other. The X-direction and the Y-direction are parallel to a main surface or a back surface of the semiconductor substrate SB, that is, are horizontal directions. The Z-direction is a thickness direction of the semiconductor substrate SB. The X-direction corresponds to a gate length direction of gate electrodes G1,G2,G3, and the Y-direction corresponds to a gate width direction of the gate electrodes G1, G2, G3.

FIG. 1 and FIG. 2 show the same planar regions. FIG. 1 and FIG. 4 show different planar regions. For simplicity, in FIG. 1, a position where the gate electrode G1 is formed is indicated by a dotted line, and an element isolation region ST, n-type semiconductor regions D1a,S1a, and n-type semiconductor regions D1b,S1b are hatched. Further, in FIG. 2, the position where the gate electrode G1 is formed is indicated by a dotted line, and the element isolation region ST and p-type halo regions HA1,HA2 are hatched. In addition, in FIG. 4, positions where the gate electrodes G2,G3 are formed are indicated by a dotted line, and the element isolation region ST, n-type semiconductor regions D2a,S2a,D3a,S3a, and n-type semiconductor regions D2b,S2b,D3b,S3b are hatched.

In the present embodiment, the semiconductor device includes a plurality of MISFETs (Metal Insulator Semiconductor Field Effect Transistor) each having the halo region (pocket region) and a plurality of MISFETs each having no halo region (pocket region). FIG. 1 to FIG. 3 show plan views (FIG. 1, FIG. 2) or a cross-sectional view (FIG. 3) of a MISFET forming region 1A which is a region (active region) in which a MISFET 1 having the halo region (pocket region) is formed. FIG. 4 and FIG. 5 show a plan view (FIG. 4) or a cross-sectional view (FIG. 5) of MISFET forming regions 2A,3A which are regions (active regions) in which the MISFETs 2,3 having no halo region (pocket region) are formed.

As will be described later, the semiconductor device in the present embodiment includes the oscillation circuit. The MISFETs 2,3 having no halo regions are used as a MISFET configuring a pair transistor included in the oscillation circuit.

In the following description, the MISFETs 1,2,3 are described as n-channel type transistors, but may be p-channel type transistors.

As shown in FIG. 1 to FIG. 6, the semiconductor substrate (semiconductor wafer) SB made of a p-type monocrystalline silicon or the like having a resistivity of, for example, about 1 Ωcm to 10 Ωcm includes the element isolation region ST for separating elements. According to the element isolation region ST, the MISFET forming region 1A (active region) where the MISFET 1 is formed, the MISFET forming region 2A (active region) where a MISFET 2 is formed, and the MISFET forming region 3A (active region) where a MISFET 3 is formed are defined.

The element isolation region ST is buried in the trench in the main surface of the semiconductor substrate SB. Each of the MISFET forming regions 1A,2A,3A is surrounded by the element isolation region ST in plan view. FIG. 1, FIG. 2, and FIG. 4 show cases where the planar shape of each of the MISFET forming regions 1A,2A,3A is a rectangular shape having sides substantially parallel to the X-direction and sides substantially parallel to the Y-direction. Note that the plan view corresponds to a plan view that is substantially parallel to the main surface of the semiconductor substrate SB.

The element isolation region ST is formed by an STI (Shallow Trench Isolation) method. For this reason, the element isolation region ST is formed of an insulator (dielectric film) buried in the trench formed in the semiconductor substrate SB. The element isolation region ST is mainly formed of silicon oxide.

A p-type well (p-type well region) PW1 is formed in the semiconductor substrate SB in the MISFET forming region 1A and a p-type well (p-type well region) PW2 is formed in the semiconductor substrate SB in the MISFET forming regions 2A,3A. The p-type wells PW1,PW2 are p-type semiconductor regions into which a p-type impurity is implanted. The depth positions of the bottom surfaces of the p-type wells PW1,PW2 are deeper than the depth position of the bottom surface of the element isolation region ST. The MISFET forming region 2A and the MISFET forming region 3A are adjacent to each other in plan view via the element isolation region ST, and the p-type well PW2 is formed over the MISFET forming region 2A and MISFET forming region 3A. Therefore, in plan view, the MISFET forming regions 2A,3A are included in the p-type well PW2.

Hereinafter, the configurations of the MISFETs 1,2,3 will be described.

### Configuration of MISFET 1

First, the configuration of the MISFET 1 will be described in detail with reference to FIG. 1 to FIG. 3.

The MISFET 1 includes the gate electrode G1 formed on the semiconductor substrate SB (p-type well PW1) in the MISFET forming region 1A via a gate dielectric film GF1, and n-type semiconductor regions S1,D1 acting as source/drain (source and/or drain) formed on both sides of the gate electrode G1 and in the semiconductor substrate in plan view.

The gate electrode G1 extends in the Y-direction so as to be across the MISFET forming region 1A in plan view. Therefore, the gate electrode G1 is continuously formed over the semiconductor substrate SB in the MISFET forming region 1A and the element isolation region ST around the MISFET forming region 1A. The gate dielectric film GF1 is interposed between the semiconductor substrate SB (p-type well PW1) and the gate electrode G1. The element isolation region ST and the gate electrode G1 may be in contact with each other, although the gate dielectric film GF1 may be interposed between the element isolation region ST and the gate electrode G1.

A region under the gate electrode G1 and in the semiconductor substrate SB (p-type well PW1) in the MISFET forming region 1A is a region in which a channel is formed, that is, a channel forming region. The channel forming region of the MISFET 1 is formed in the surface layer portion of the semiconductor substrate SB and is adjacent to the gate dielectric film GF1 located under the gate electrode G1.

Sidewall spacers SW are formed as sidewall dielectric film on the sidewalls of the gate electrode G1. The sidewall spacers SW are formed of dielectric films, and may be formed of a single film or a stacked film.

In plan view, a pair of n-type semiconductor regions D1,S1 is formed so as to sandwich the gate electrode G1 in the X-direction, one of which (here, the n-type semiconductor region S1) functions as a source region of the MISFET 1, and the other of which (here, the n-type semiconductor region D1) functions as a drain region of the MISFET 1. The n-type semiconductor regions D1,S1 are formed in the semiconductor substrate SB (p-type well PW1) in the MISFET forming region 1A. The pair of n-type semiconductor regions D1,S1 has an LDD (Lightly doped Drain) structure.

Therefore, the n-type semiconductor region S1 is formed of the n-type semiconductor region (extension region, low concentration region) S1a having a low impurity concentration and the n-type semiconductor region (high concentration region) S1b having an impurity concentration higher than the impurity concentration of the n-type semiconductor region S1a.

The n-type semiconductor region D1 is formed of the n-type semiconductor region (extension region, low concentration region) D1a having a low impurity concentration and the n-type semiconductor region (high concentration region) D1b having an impurity concentration higher than the impurity concentration of the n-type semiconductor region D1a. The impurity concentration (n-type impurity concentration) of the n-type semiconductor region D1b is higher than the impurity concentration (n-type impurity concentration) of the n-type semiconductor region D1a, and the impurity concentration (n-type impurity concentration) of the n-type semiconductor region S1b is higher than the impurity concentration (n-type impurity concentration) of the n-type semiconductor region S1a.

The n-type semiconductor regions D1a,S1a are formed in a self-aligned manner with the gate electrode G1, and the n-type semiconductor regions D1b,S1b is formed in a self-aligned manner with the sidewall spacers SW formed on the sidewalls of the gate electrode G1. Therefore, the n-type semiconductor region D1a is located under the sidewall spacer SW on one sidewall of the gate electrode G1, the n-type semiconductor region S1a is located under the sidewall spacer SW on the other sidewall of the gate electrode G1, and the n-type semiconductor region D1a and the n-type semiconductor region S1a are spaced apart from each other with the channel forming region interposed therebetween (spaced apart in the X-direction). The n-type semiconductor regions D1b,S1b having high concentrations are formed on the outer side (away from the channel forming region) of the n-type semiconductor regions D1a,S1a having low concentrations. The n-type semiconductor region D1b is formed at a position being adjacent to the n-type semiconductor region D1a and being spaced apart from the channel forming region by an amount corresponding to the n-type semiconductor region D1a (spaced apart in the X-direction). The n-type semiconductor region S1b is formed at a position being adjacent to the n-type semiconductor region S1a and being spaced apart from the channel forming region by an amount corresponding to the n-type semiconductor region S1a (spaced apart in the X-direction). The n-type semiconductor region D1a is interposed between the channel forming region and the n-type semiconductor region D1b, and the n-type semiconductor region S1a is interposed between the channel forming region and the n-type semiconductor region S1b.

Each of the n-type semiconductor regions D1,S1 is formed in the semiconductor substrate SB (p-type well PW1) in the MISFET forming region 1A, and extends in the Y-direction along the gate electrode G1. Therefore, each of the n-type semiconductor region D1a and the n-type semiconductor region D1b configuring the n-type semiconductor region D1 extends in the Y-direction along the gate electrode G1, and each of the n-type semiconductor region S1a and the n-type semiconductor region S1b configuring the n-type semiconductor region S1 extends in the Y-direction along the gate electrode G1.

### Configuration of MISFET 2

Next, the configuration of the MISFET 2 will be described with reference to FIG. 4 to FIG. 6.

The MISFET 2 includes the gate electrode G2 formed on the semiconductor substrate SB in the MISFET forming region 2A (on the p-type well PW2) via a gate dielectric film GF2, and n-type semiconductor regions D2,S2 acting as source/drain (source or drain) formed on both sides of the gate electrode G2 and in the semiconductor substrate SB in plan view.

The n-type semiconductor regions D2,S2 are formed in the semiconductor substrate SB (p-type well PW2) in the MISFET forming region 2A. The n-type semiconductor region D2 includes the n-type semiconductor region (extension region, low concentration region) D2a having a low impurity concentration and the n-type semiconductor region (high concentration region) D2b having an impurity concentration higher than the impurity concentration of the n-type semiconductor region D2a. The n-type semiconductor region S2 includes the n-type semiconductor region (extension region, low concentration region) S2a having a low impurity concentration and the n-type semiconductor region (high concentration region) S2b having an impurity concentration higher than the impurity concentration of the n-type semiconductor region S2a.

Since the above description of the “CONFIGURATION OF MISFET 1” can be applied to the description of the gate electrode G2, the gate dielectric film GF2, the n-type semiconductor region D2, the n-type semiconductor region D2a, the n-type semiconductor region D2b, the n-type semiconductor region S2, the n-type semiconductor region S2a, the n-type semiconductor region S2b, and the sidewall spacers SW, repetitive description thereof will be omitted here. However, when the description in “CONFIGURATION OF MISFET 1” is used as the description in the “CONFIGURATION OF MISFET 2”, the following replacement of terms is required. That is, the “MISFET 1” is read as the “MISFET 2”, the “MISFET forming region 1A” is read as the “MISFET forming region 2A”, the “p-type well PW1” is read as the “p-type well PW2”, the “gate electrode G1” is read as the “gate electrode G2”, and the “gate dielectric film GF1” is read as the “gate dielectric film GF2”. Further, the “n-type semiconductor region D1” is read as the “n-type semiconductor region D2”, the “n-type semiconductor region D1a” is read as the “n-type semiconductor region D2a”, and the “n-type semiconductor region D1b” is read as the “n-type semiconductor region D2b”. Further, the “n-type semiconductor region S1” is read as the “n-type semiconductor region S2”, the “n-type semiconductor region S1a” is read as the “n-type semiconductor region S2a”, and the “n-type semiconductor region S1b” is read as the “n-type semiconductor region S2b”.

### Configuration of MISFET 3

Next, the configuration of the MISFET 3 will be described with reference to FIG. 4 to FIG. 6.

The configuration of the MISFET 2 and the configuration of the MISFET 3 are basically the same as each other. The MISFET 3 includes the gate electrode G3 formed on the semiconductor substrate SB in the MISFET forming region 3A (on the p-type well PW2) via a gate dielectric film GF3, and n-type semiconductor regions D3,S3 acting as source/drain formed on both sides of the gate electrode G3 and in the semiconductor substrate SB in plan view.

The n-type semiconductor regions D3,S3 are formed in the semiconductor substrate SB (p-type well PW2) in the MISFET forming region 3A. The n-type semiconductor region D3 includes the n-type semiconductor region (extension region, low concentration region) D3a having a low impurity concentration and the n-type semiconductor region (high concentration region) D3b having an impurity concentration higher than the impurity concentration of the n-type semiconductor region D3a. The n-type semiconductor region S3 includes the n-type semiconductor region (extension region, low concentration region) S3a having a low impurity concentration and the n-type semiconductor region (high concentration region) S3b having an impurity concentration higher than the impurity concentration of the n-type semiconductor region S3a.

Since the above description of the “CONFIGURATION OF MISFET 1” can be applied to the description of the gate electrode G3, the gate dielectric film GF3, the n-type semiconductor region D3, the n-type semiconductor region D3a, the n-type semiconductor region D3b, the n-type semiconductor region S3, the n-type semiconductor region S3a, the n-type semiconductor region S3b, and the sidewall spacers SW, repetitive description thereof will be omitted here. However, when the description in “CONFIGURATION OF MISFET 1” is used as the description in the “CONFIGURATION OF MISFET 3”, the following replacement of terms is required. That is, the “MISFET 1” is read as the “MISFET 3”, the “MISFET forming region 1A” is read as the “MISFET forming region 3A”, the “p-type well PW1” is read as the “p-type well PW2”, the “gate electrode G1” is read as the “gate electrode G3”, and the “gate dielectric film GF1” is read as the “gate dielectric film GF3”. Further, the “n-type semiconductor region D1” is read as the “n-type semiconductor region D3”, the “n-type semiconductor region D1a” is read as the “n-type semiconductor region D3a”, and the “n-type semiconductor region D1b” is read as the “n-type semiconductor region D3b”. Further, the “n-type semiconductor region S1” is read as the “n-type semiconductor region S3”, the “n-type semiconductor region S1a” is read as the “n-type semiconductor region S3a”, and the “n-type semiconductor region S1b” is read as the “n-type semiconductor region S3b”.

### P-Type Halo Region

The MISFET 1 further includes the p-type halo regions (p-type semiconducting region, p-type pocket region) HA1,HA2 formed in the semiconductor substrate SB (p-type well PW1) in the MISFET forming region 1A. In contrast, the MISFET 2 and the MISFET 3 do not include p-type halo regions (p-type pocket regions). Therefore, regions corresponding to the p-type halo regions HA1,HA2 are not formed in the semiconductor substrate SB (p-type well PW2) in the MISFET forming region 2A and in the semiconductor substrate SB (p-type well PW2) in the MISFET forming region 3A. Hereinafter, the p-type halo regions HA1,HA2 of the MISFET 1 will be described.

As shown in FIG. 3, the p-type halo region HA1 is formed so as to cover the n-type semiconductor region D1a in the cross-sectional view (cross-sectional view substantially orthogonal to the Y-direction), and the p-type halo region HA2 is formed so as to cover the n-type semiconductor region S1a in the cross-sectional view (cross-sectional view substantially orthogonal to the Y-direction).

Therefore, the p-type halo region HA1 is adjacent to the side surface (the side surface facing the n-type semiconductor region S1a) and the lower surface of the n-type semiconductor region D1a, and the p-type halo region HA2 is adjacent to the side surface (the side surface facing the n-type semiconductor region D1a) and the lower surface of the n-type semiconductor region S1a. A portion of each of the p-type halo regions HA1,HA2 overlaps with the gate electrode G1 in plan view. The p-type halo regions HA1,HA2 have conductivity types opposite to the conductivity types of the n-type semiconductor regions D1a,S1a,D1b,S1b and the same conductivity type as the conductivity type of the p-type well PW1, and has an impurity concentration (p-type impurity concentration) higher than the impurity concentration of the p-type well PW1. The p-type impurity concentrations of the p-type halo regions HA1,HA2 can be, for example, about 2×10¹⁷ to 1×10¹⁹ cm³. The p-type impurity concentration of the p-type well PW1 can be, for example, about 1×10¹⁷ to 5×10¹⁸ cm³.

As will be described later, the ion implantation for forming the p-type halo regions HA1,HA2 uses an oblique ion implantation, whereby the p-type halo regions HA1,HA2 can be formed so as to cover the n-type semiconductor regions D1a,S1a. In general ion implantation (vertical ion implantation), impurity ions are accelerated and injected in a direction orthogonal to the main surface of the semiconductor substrate SB, but in oblique ion implantation, impurity ions are accelerated and injected in a direction inclined at a predetermined angle from the direction orthogonal to the main surface of the semiconductor substrate SB.

In the X-direction, the n-type semiconductor region D1a and the p-type halo region HA1 are adjacent to each other and the n-type semiconductor region S1a and the p-type halo region HA2 are adjacent to each other. A portion of the p-type halo region HA1 adjacent to the n-type semiconductor region D1a in the X-direction is located under the gate electrode G1, and a portion of the p-type halo region HA2 adjacent to the n-type semiconductor region S1a in the X-direction is located under the gate electrode G1. From another viewpoint, a portion adjacent to the n-type semiconductor region D1a in the X-direction of the p-type halo region HA1 overlaps with the gate electrode G1 in plan view, and a portion adjacent to the n-type semiconductor region S1a in the X-direction of the p-type halo region HA2 overlaps with the gate electrode G1 in plan view. The p-type halo regions HA1,HA2 (that is, the p-type halo regions HA1,HA2 overlapping with the gate electrode G1 in plan view) located under the gate electrode G1 can function as a part of the channel forming region.

### MISFETs 1, 2, 3

the gate dielectric film GF1 of the MISFET 1, the gate dielectric film GF2 of the MISFET 2 and the gate dielectric film GF3 of the MISFET 3 are formed in the same manufacturing step. For this reason, the gate dielectric film GF1, the gate dielectric film GF2 and the gate dielectric film GF3 are formed of the same dielectric material (for example, silicon oxide), and the thickness of the gate dielectric film GF1, the thickness of the gate dielectric film GF2, and the thickness of the gate dielectric film GF3 are the same as one another.

The gate electrode G1 of the MISFET 1, the gate electrode G2 of the MISFET 2, and the gate electrode G3 of the MISFET 3 are formed in the same manufacturing step. That is, the gate electrode G1, the gate electrode G2, and the gate electrode G3 are formed by patterning a common conductive film (for example, a polysilicon film). Therefore, the gate electrode G1, the gate electrode G2, and the gate electrode G3 are made of the same conductive material (for example, polysilicon), and the thickness of the gate electrode G1, the thickness of the gate electrode G2, and the thickness of the gate electrode G3 are the same as one another.

The n-type semiconductor regions D1a,S1a and the p-type halo regions HA1,HA2 of the MISFET 1 are formed after forming the gate electrode G1 and prior to forming the sidewall spacers SW on the sidewalls of the gate electrode G1. The n-type semiconductor regions D1a,S1a are formed by the vertical ion implantation using n-type impurities, and the p-type halo regions HA1,HA2 are formed by the oblique ion implantation using p-type impurities.

The n-type semiconductor regions D2a,S2a of the MISFET 2 are formed by the vertical ion implantation with n-type impurities after forming the gate electrode G2 and prior to forming the sidewall spacers SW on the sidewalls of the gate electrode G2. The n-type semiconductor regions D3a,S3a of the MISFET 3 are formed by vertical ion implantation using n-type impurities after forming the gate electrode G3 and prior to forming the sidewall spacers SW on the sidewalls of the gate electrode G3.

Since the MISFET 2 does not have a p-type halo region, an oblique ion implantation with p-type impurities is not performed to the semiconductor substrate SB (p-type well PW2) in the MISFET forming region 2A after forming the gate electrode G2 and prior to forming the sidewall spacers SW on the sidewalls of the gate electrode G2. Further, since the MISFET 3 does not have a p-type halo region, an oblique ion implantation using p-type impurities is not performed to the semiconductor substrate SB (p-type well PW2) in the MISFET forming region 3A after forming the gate electrode G3 and prior to forming the sidewall spacers SW on the sidewalls of the gate electrode G3. This can be realized by performing an oblique ion implantation for forming the p-type halo regions HA1,HA2 in a state where a photoresist pattern covering the semiconductor substrate SB and the gate electrodes G2,G3 in the MISFET forming regions 2A,3A and exposing the semiconductor substrate SB and the gate electrode G1 in the MISFET forming region 1A is formed.

Since the n-type semiconductor regions D2b,S2b and the n-type semiconductor regions D3b,S3b are formed in the same ion implantation step, the impurity concentrations (n-type impurity concentrations) of the n-type semiconductor regions D2b,S2b and the impurity concentrations (n-type impurity concentrations) of the n-type semiconductor regions D3b,S3b are the same as one another.

### Structure Above Semiconductor Substrate SB

Next, the structure of the semiconductor substrate SB will be described.

As shown in FIGS. 3, 5, and 6, an interlayer dielectric film IL is formed as a dielectric film on the semiconductor substrate SB so as to cover the gate electrodes G1,G2,G3 and the sidewall spacers SW. The interlayer dielectric film IL is formed of, for example, a silicon oxide film. The interlayer dielectric film IL can also be formed by a stacked film of a relatively thin silicon nitride film and a relatively thick silicon oxide film on the silicon nitride. An upper surface of the interlayer dielectric film IL is planarized.

A contact hole (through-hole) is formed in the interlayer dielectric film IL, and a conductive plug (contact plug) PG including a tungsten (W) film as a main component is formed (buried) in the contact hole. A plurality of plugs PG are formed, and each of the plurality of plugs PG penetrates through the interlayer dielectric film IL. The plug PG is formed on each of the n-type semiconductor regions D1b,S1b,D2b,S2b,D3b,S3b and the gate electrodes G1,G2,G3. Each of the n-type semiconductor regions D1b,S1b,D2b,S2b,D3b,S3b and the gate electrodes G1,G2,G3 is electrically connected to the plug PG disposed thereon.

When a metal silicide layer (not shown) is formed on each upper portion (surface layer portion) of the n-type semiconductor regions D1b,S1b,D2b,S2b,D3b,S3b and the gate electrodes G1,G2,G3, each plug PG is in contact with the metal silicide layer, and is electrically connected to each region under the metal silicide layer via the metal silicide layer.

Wirings (first layer wirings) M1 made of a conductive film mainly formed of aluminum (Al), aluminum alloy, or the like are formed on the interlayer dielectric film IL in which the plug PG is buried. The wiring M1 is not limited to aluminum wiring, but may also be wiring using other metal materials, such as tungsten wiring or copper wiring. Each of the plugs PG is electrically connected to the wiring M1.

A structure above the interlayer dielectric film IL and the wirings M1 are not shown and described here. In practice, an upper wiring and a dielectric film are formed.

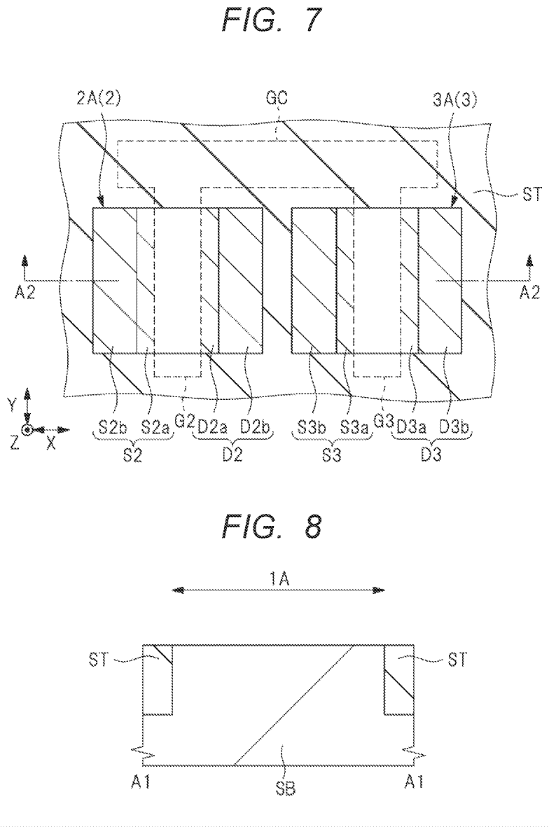

The gate electrode G2 of the MISFET 2 is electrically connected to the gate electrode G3 of the MISFET 3. In FIGS. 4 and 6, the gate electrode G2 of the MISFET 2 and the gate electrode G3 of the MISFET 3 are electrically connected to each other via the plug PG disposed on the gate electrode G2, the plug PG disposed on the gate electrode G3, and the wiring M1 (a gate wiring M1G shown in FIG. 6) connecting them. Note that, as a method of electrically connecting the gate electrode G2 of the MISFET 2 and the gate electrode G3 of the MISFET 3, the gate electrode G2 and the gate electrode G3 can be integrally connected to each other, which is shown in FIG. 7. FIG. 7 is a plan view of the main portion of the semiconductor device according to the modified example of the present embodiment, corresponding to FIG. 4. In FIG. 7, one end portion of the gate electrode G2 extending in the Y-direction and one end portion of the gate electrode G3 extending in the Y-direction are integrally connected to a gate connecting portion GC extending in the X-direction. The gate connecting portion GC is formed integrally with the gate electrodes G2,G3 and is disposed on the element isolation region ST. Accordingly, the gate electrode G2 of the MISFET 2 and the gate electrode G3 of the MISFET 3 are electrically connected to each other via the gate connecting portion GC. In this case, the gate electrode G2 of the MISFET 2 and the gate electrode G3 of the MISFET 3 may not be connected with each other by the gate wiring M1G. Since the gate connecting portion GC is formed integrally with the gate electrodes G2,G3, the gate connecting portion GC is formed in the same manufacturing step as the gate electrodes G2,G3 and is made of the same material (for example, polysilicon) as the gate electrodes G2,G3. The sidewall spacers SW are also formed on the sidewalls of the gate connecting portion GC.

### Manufacturing Steps of Semiconductor Device

Next, the manufacturing method of the semiconductor device according to the present embodiment will be described with reference to the drawings.

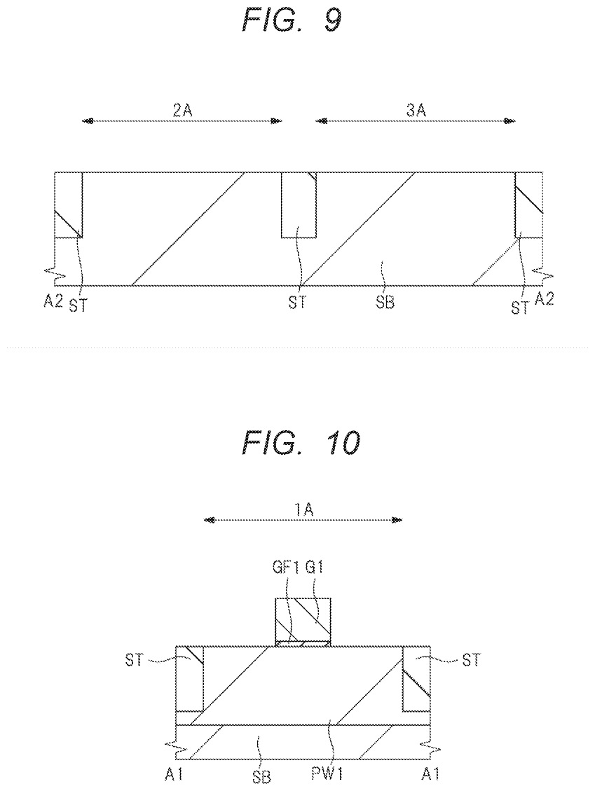

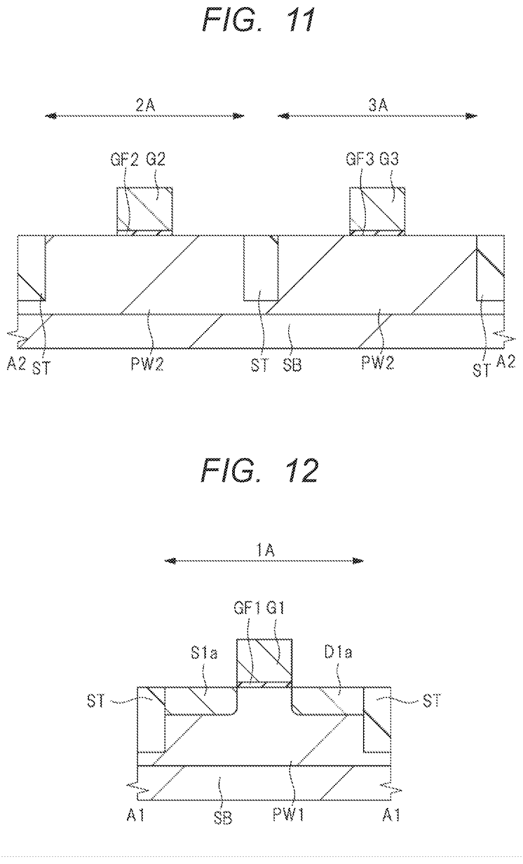

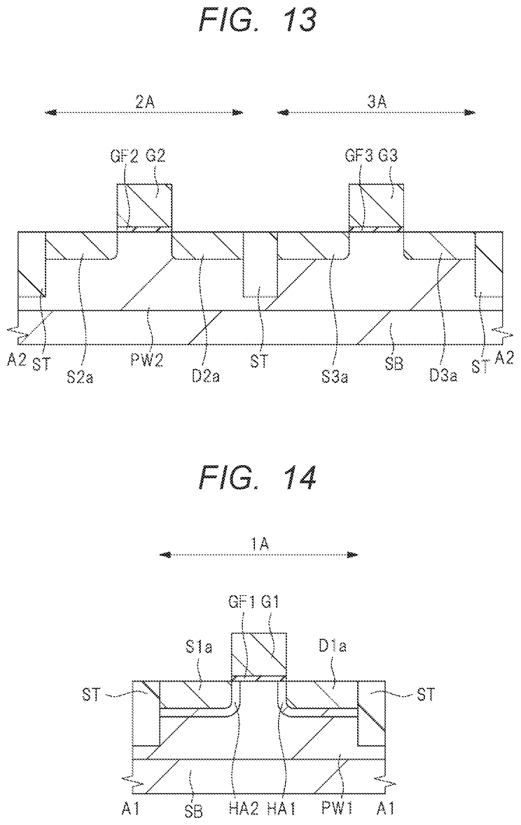

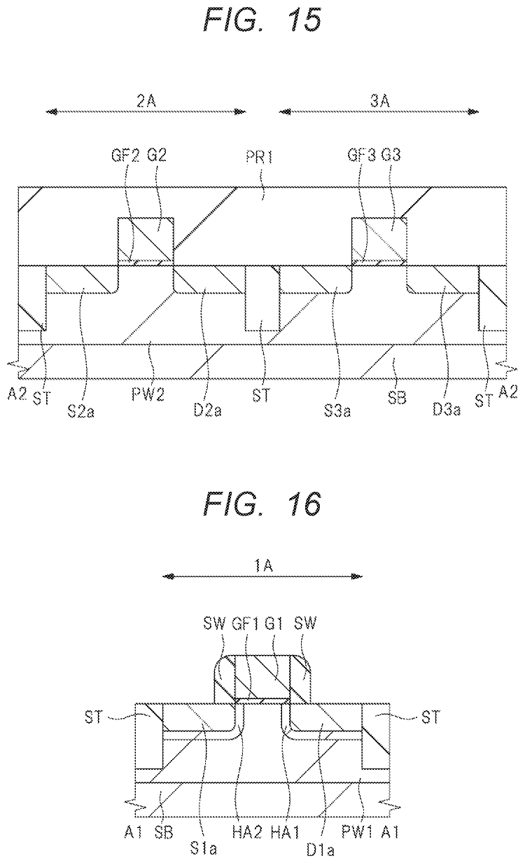

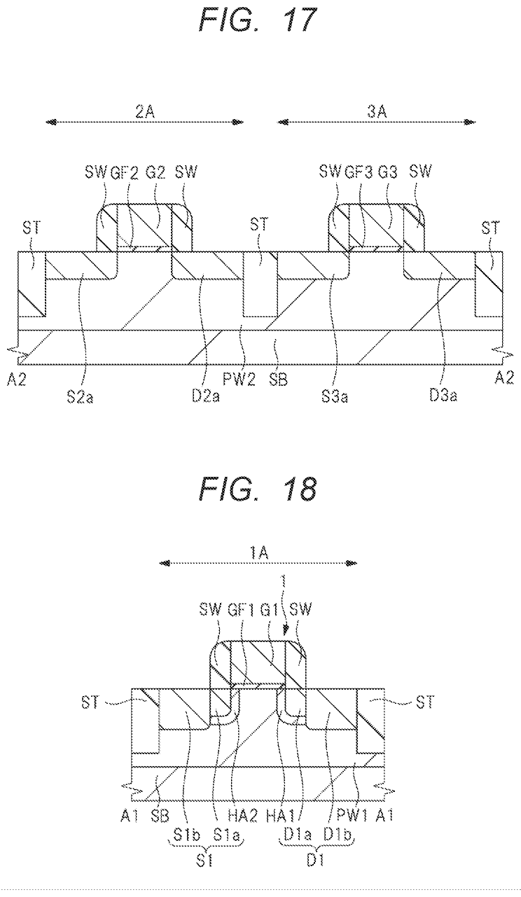

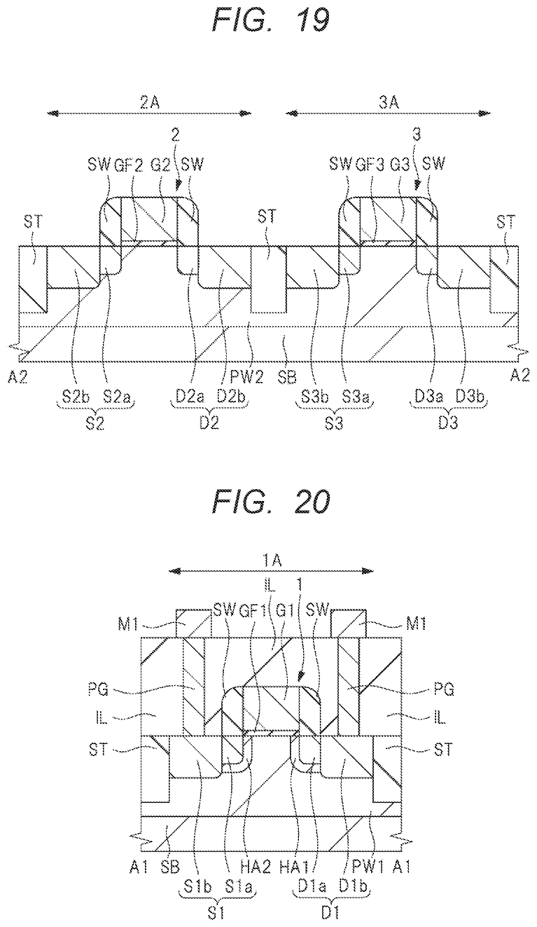

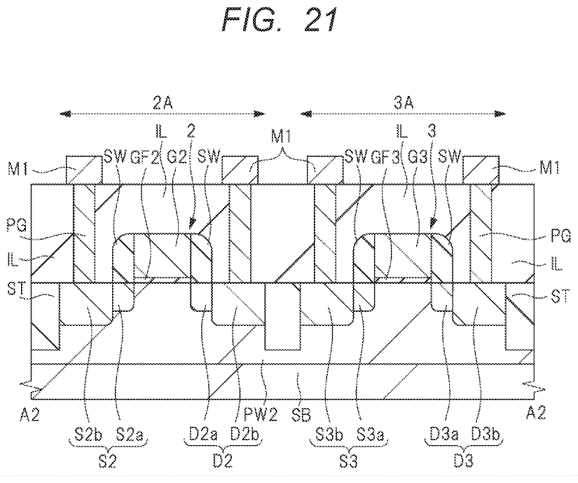

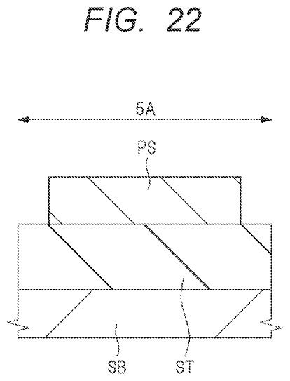

FIG. 8 to FIG. 21 are cross-sectional views of the main portions of the semiconductor device in the manufacturing step according to the present embodiment. Of these, FIG. 8, FIG. 10, FIG. 12, FIG. 14, FIG. 16, FIG. 18, and FIG. 20 show cross sections substantially corresponding to the above-described FIG. 3 (a cross section along A1-A1 line in FIG. 1), and FIG. 9, FIG. 11, FIG. 13, FIG. 15, FIG. 17, FIG. 19, and FIG. 21 show cross sections substantially corresponding to the above-described FIG. 5 (a cross section along A2-A2 line in FIG. 4).

As shown in FIGS. 8 and 9, a semiconductor substrate (semiconductor wafer) SB made of p-type monocrystalline silicon or the like having a resistivity of, for example, about 1 Ωcm to 10 Ωcm is prepared. Then, the element isolation region ST is formed in the main surface of the semiconductor substrate SB. The element isolation region ST is formed of an insulator such as silicon oxide and can be formed by the STI method.

Next, as shown in FIGS. 10 and 11, the p-type well PW1 and the p-type well PW2 are formed in the semiconductor substrate SB using the ion implantation. The p-type well PW1 and the p-type well PW2 can be formed by the same ion implantation step, and in such case, the impurity concentration (p-type impurity concentration) of the p-type well PW1 and the impurity concentration (p-type impurity concentration) of the p-type well PW2 are substantially the same as each other. The p-type well PW1 and the p-type well PW2 are formed from the main surface of the semiconductor substrate SB to a predetermined depth, and the MISFET forming region 1A is included in the p-type well PW1 in plan view and the MISFET forming regions 2A,3A are included in the p-type well PW2 in plan view.

Next, as shown in FIGS. 10 and 11, the gate electrode G1 is formed on the semiconductor substrate SB (p-type well PW1) in the MISFET forming region 1A via the gate dielectric film GF1, the gate electrode G2 is formed on the semiconductor substrate (p-type well PW2) in the MISFET forming region 2A via the gate dielectric film GF2, and the gate electrode G3 is formed on the semiconductor substrate SB (p-type well PW2) in the MISFET forming region 3A via the gate dielectric film GF3. This manufacturing step can be performed, for example, as follows.

That is, after a dielectric film for the gate dielectric films is formed on the main surface of the semiconductor substrate SB, a conductive film (for example, a polysilicon film) for forming the gate electrodes G1,G2,G3 is formed thereon, and then the conductive film is patterned using a photolithography method and a dry etching method to form the gate electrodes G1,G2,G3. The dielectric film (the dielectric film for gate dielectric film) remaining under each of the gate electrodes G1,G2,G3 becomes the gate dielectric films GF1,GF2,GF3. Therefore, the thicknesses of the gate dielectric films GF1,GF2,GF3 are the same as one another, and the thicknesses of the gate electrodes G1,G2,G3 are the same as one another.

Next, as shown in FIGS. 12 and 13, the n-type semiconductor regions D1a,S1a,D2a,S2a,D3a,S3a are formed by vertical ion implantation using n-type impurities.

In this ion implantation, the gate electrodes G1,G2,G3 can function as masks (ion implantation blocking mask). Therefore, the n-type semiconductor regions D1a,S1a are formed on both sides of the gate electrode G1 and in the semiconductor substrate SB (p-type well PW1) in the MISFET forming region 1A. The n-type semiconductor regions D2a,S2a are formed on both sides of the gate electrode G2 and in the semiconductor substrate SB (p-type well PW2) in the MISFET forming region 2A. The n-type semiconductor regions D3a,S3a are formed on both sides of the gate electrode G3 and in the semiconductor substrate SB (p-type well PW2) in the MISFET forming region 3A. Impurities are not implanted in a region immediately below the gate electrodes G1,G2,G3 in the semiconductor substrate SB. The n-type semiconductor regions D1a,S1a, the n-type semiconductor regions D2a,S2a, and the n-type semiconductor regions D3a,S3a can be formed by the same ion implantation step, and in such case, their impurity concentrations (n-type impurity concentrations) are the same as one another.

Further, after the gate electrodes G1,G2,G3 are formed, a photoresist pattern (not shown) is formed on the semiconductor substrate SB by a photolithography technique, and ion implantation for forming the n-type semiconductor regions D1a,S1a,D2a,S2a,D3a,S3a can be performed while the photoresist pattern is formed. In such case, the MISFET forming regions 1A,2A,3A may not be covered with the photoresist pattern. The photoresist pattern is removed after the n-type semiconductor regions D1a,S1a,D2a,S2a,D3a,S3a are formed.

Next, as shown in FIGS. 14 and 15, a photoresist pattern (resist pattern) PR1 is formed on the semiconductor substrate SB using a photolithography technique. The photoresist pattern PR1 is formed to cover the MISFET forming region 2A,3A and to expose the MISFET forming region 1A. Note that the MISFET forming region 1A can be regarded as a region in the semiconductor substrate SB in which the MISFET 1 is to be formed. In addition, the MISFET forming region 2A can be regarded as a region in the semiconductor substrate SB where the MISFET 2 is to be formed. In addition, the MISFET forming region 3A can be regarded as a region in the semiconductor substrate SB where the MISFET 3 is to be formed.

Next, as shown in FIGS. 14 and 15, the p-type halo regions HA1,HA2 are formed in the semiconductor substrate SB (p-type well PW1) in the MISFET forming region 1A by the oblique ion implantation using p-type impurities.

In this ion implantation, the gate electrode G1 can function as a mask (ion implantation blocking mask), and since the oblique ion implantation is performed, the p-type halo region HA1 is formed so as to surround (cover) the n-type semiconductor region D1a, and the p-type halo region HA2 is formed so as to surround (cover) the n-type semiconductor region S1a. A portion of each of the p-type halo regions HA1,HA2 is located immediately below the gate electrode G1 (that is, overlaps with the gate electrode G1 in plan view). The p-type halo region HA1 and the p-type halo region HA2 are spaced apart from each other in the Y-direction. The p-type halo regions HA1,HA2 have the same conductivity type as the p-type well PW, but have p-type impurity concentrations higher than the impurity concentration of the p-type well PW.

In the ion implantation for forming the p-type halo regions HA1,HA2, the photoresist pattern PR1 can also function as a mask (ion implantation blocking mask), and therefore the p-type impurities are not implanted into the semiconductor substrate SB (p-type well PW2) in the MISFET forming regions 2A,3A. After forming the gate electrodes G1,G2,G3 and prior to forming the sidewall spacers SW, impurities of the same conductivity type as the p-type well PW2 (p-type impurities) are not ion-implanted into the semiconductor substrate SB (p-type well PW2) in the MISFET forming regions 2A,3A. Therefore, the p-type halo regions (corresponding to the p-type halo regions HA1,HA2) are not formed in the semiconductor substrate SB (p-type well PW2) in the MISFET forming region 2A,3A.

After the p-type halo regions HA1,HA2 are formed, the photoresist pattern PR1 is removed by ashing or the like.

Next, as shown in FIGS. 16 and 17, the sidewall spacers SW made of, for example, silicon oxide or silicon nitride or a stacked film thereof are formed on the sidewalls of the gate electrodes G1,G2,G3. The sidewall spacers SW can be formed, for example, by depositing a silicon oxide film or a silicon nitride film or a stacked film thereof on the main surface of the semiconductor substrate SB, and then etching back the silicon oxide film, the silicon nitride film or the stacked film using an anisotropic etching technique.

Next, as shown in FIGS. 18 and 19, the n-type semiconductor regions D1b,S1b,D2b,S2b,D3b,S3b are formed by ion implantation (preferably vertical ion implantation) with n-type impurities.

In this ion implantation, the gate electrodes G1,G2,G3 and the sidewall spacers SW can function as masks (ion implantation blocking mask). Therefore, the n-type semiconductor regions D1b,S1b are formed on both sides of the structure including the gate electrode G1 and the sidewall spacers SW and in the semiconductor substrate SB (p-type well PW1) in the MISFET forming region 1A. In addition, the n-type semiconductor regions D2b,S2b are formed on both sides of the structure including the gate electrode G2 and the sidewall spacers SW and in the semiconductor substrate SB (p-type well PW2) in the MISFET forming region 2A. In addition, the n-type semiconductor regions D3b,S3b are formed on both sides of the structure including the gate electrode G3 and the sidewall spacers SW and in the semiconductor substrate SB (p-type well PW2) in MISFET forming region 3A. No impurities are implanted in the regions immediately below the gate electrode G1,G2,G3 and immediately below the sidewall spacers SW in the semiconductor substrate.

The n-type impurity concentrations of the n-type semiconductor regions D1b,S1b are higher than the n-type impurity concentrations of the n-type semiconductor regions D1a,S1a, the n-type impurity concentrations of the n-type semiconductor regions D2b,S2b are higher than the n-type impurity concentrations of the n-type semiconductor regions D2a,S2a, and the n-type impurity concentrations of the n-type semiconductor regions D3b,S3b are higher than the n-type impurity concentrations of the n-type semiconductor regions D3a,S3a. The n-type semiconductor regions D1b,S1b, the n-type semiconductor regions D2b,S2b, and the n-type semiconductor regions D3b,S3b can be formed by the same ion implantation step, and in such case, their impurity concentrations (n-type impurity concentrations) are the same as one another.

Next, if necessary, activation annealing is performed, which is a heat treatment for activating impurities implanted by ion implantation so far.

The MISFETs 1,2,3 are formed as described above.

Next, a metal silicide layer (not shown) is formed on each of the upper portions (upper layer portions) of the n-type semiconductor regions D1b,S1b,D2b,S2b,D3b,S3b and the gate electrodes G1,G2,G3 by using a Salicide (Self Aligned Silicide) technique as needed.

Next, as shown in FIGS. 20 and 21, the interlayer dielectric film IL is formed on the main surface of the semiconductor substrate SB so as to cover the gate electrodes G1,G2,G3 and the sidewall spacers SW. After the interlayer dielectric film IL is formed, the upper surface of the interlayer dielectric film IL can be polished by the CMP method or the like to improve the flatness of the interlayer dielectric film IL.

Next, contact holes are formed in the interlayer dielectric film IL, and then the plugs PG are formed in the contact holes.

Next, the wirings M1 are formed on the interlayer dielectric film IL. Thereafter, upper interlayer dielectric films and wirings are further formed in upper layer, but the illustration and explanation thereof are omitted here.

The semiconductor device according to the present embodiment is manufactured as described above.

### Modified Example of Manufacturing Method of Semiconductor Device

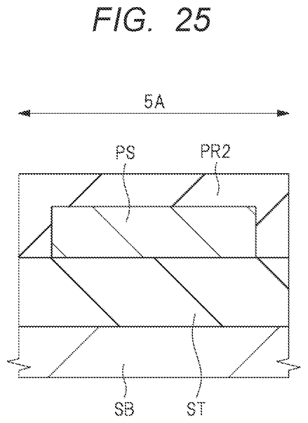

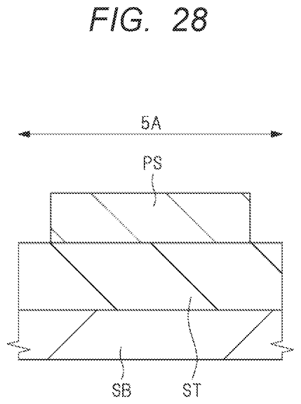

Next, the first modified example of the manufacturing step of the semiconductor device of the present embodiment will be described with reference to FIGS. 22 to 28. Here, a semiconductor device including the MISFETs 1,2,3 and a resistive element (polysilicon resistive element) PS will be described. Among FIGS. 22 to 28, FIGS. 22, 25, and 28 show cross-sectional views of a resistive element forming region 5A which is a region (planar region) in which the resistive element PS is formed. In addition, among FIGS. 22 to 28, FIGS. 23 and 26 show cross sections substantially corresponding to the above-described FIG. 3 (a cross section along A1-A1 line in FIG. 1), and FIGS. 24 and 27 show cross sections substantially corresponding to the above-described FIG. 5 (a cross section along A2-A2 line in FIG. 4).

FIG. 22 is a cross-sectional view of the resistive element forming region 5A showing the same manufacturing steps as those in FIG. 10 and FIG. 11, in which the resistive element PS is formed on the element isolation region ST. The resistive element PS is made of polysilicon and is formed in the same step as the gate electrodes G1,G2,G3. Specifically, the gate electrodes G1,G2,G3 and the resistive element PS can be formed together by forming a dielectric film for the gate dielectric films on the main surface of the semiconductor substrate SB, forming a polysilicon film serving as both the gate electrodes forming purpose and the resistive element forming purpose, and then patterning the polysilicon film using a photolithography method and a dry etching method.

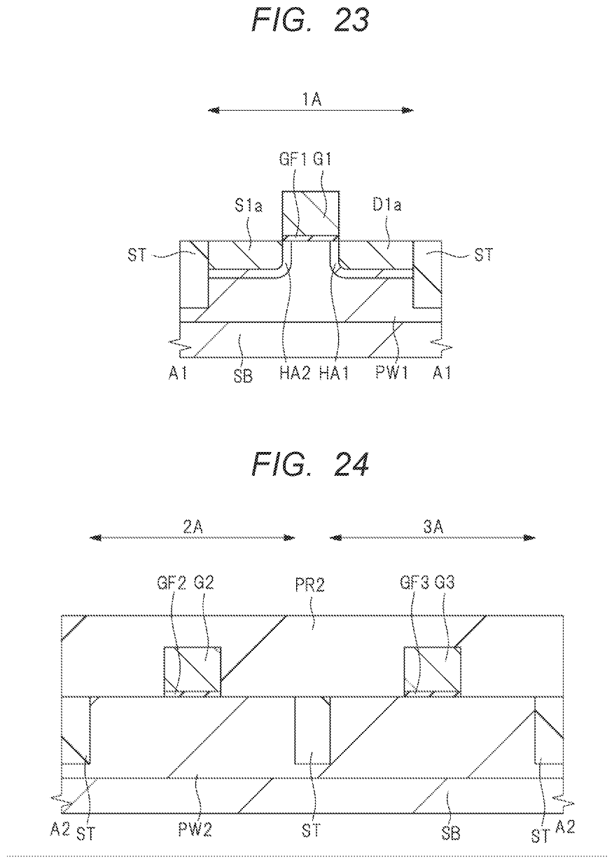

After the gate electrodes G1,G2,G3 and the resistive element PS are formed, as shown in FIGS. 23 to 25, a photoresist pattern (resist pattern) PR2 is formed on the semiconductor substrate SB using a photolithography technique. The photoresist pattern PR2 is formed so as to cover the MISFET forming regions 2A,3A and the resistive element forming region 5A and to expose the MISFET forming region 1A. The resistive element forming region 5A can be regarded as a region in the semiconductor substrate SB where the resistive element PS is to be formed. The resistive element PS is covered with the photoresist pattern PR2.

Next, as shown in FIGS. 23 to 25, the n-type semiconductor regions D1a,S1a are formed in the semiconductor substrate SB (p-type well PW1) in the MISFET forming region 1A by vertical ion implantation using n-type impurities. In the ion implantation for forming the n-type semiconductor regions D1a,S1a, since the photoresist pattern PR2 can also function as a mask (ion implantation blocking mask), the n-type impurities are not implanted into the semiconductor substrate SB (p-type well PW2) in the MISFET forming regions 2A,3A and the resistive element PS in the resistive element forming region 5A.

Next, as shown in FIGS. 23 to 25, the p-type halo regions HA1,HA2 are formed in the semiconductor substrate SB (p-type well PW1) in the MISFET forming region 1A by oblique ion implantation using p-type impurities. In the ion implantation for forming the p-type halo regions HA1,HA2, since the photoresist pattern PR2 can also function as a mask (ion implantation blocking mask), the p-type impurities are not implanted into the semiconductor substrate SB (p-type well PW2) in the MISFET forming regions 2A,3A and the resistive element PS in the resistive element forming region 5A.

Note that either of the vertical ion implantation for forming the n-type semiconductor regions D1a,S1a and the oblique ion implantation for forming the p-type halo regions HA1,HA2 may be performed first.

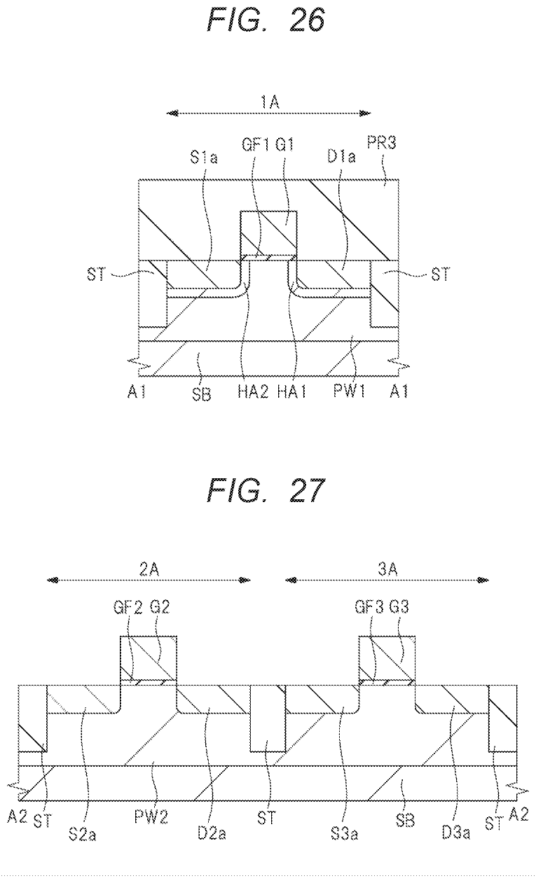

Next, after the photoresist pattern PR2 is removed by ashing or the like, as shown in FIGS. 26 to 28, a photoresist pattern (resist pattern) PR3 is formed on the semiconductor substrate SB using a photolithography technique. The photoresist pattern PR3 is formed so as to cover the MISFET forming region 1A and to expose the MISFET forming regions 2A,3A and the resistive element forming region 5A. The resistive element PS is exposed without being covered with the photoresist pattern PR3.

Next, as shown in FIGS. 26 to 28, the n-type semiconductor regions D2a,S2a,D3a,S3a are formed in the semiconductor substrate SB (p-type well PW2) in the MISFET forming regions 2A,3A by the vertical ion implantation using n-type impurities. At this time, the n-type impurities are also implanted into the resistive element PS because the resistive element PS is exposed without being covered with the photoresist pattern PR3. As a result, the resistive element PS is adjusted to an impurity concentration suitable for the resistive element. Since the n-type semiconductor regions D2b,S2b,D3b,S3b can be formed by the same ion implantation step, their impurity concentrations (n-type impurity concentrations) are the same as one another. The impurity concentrations (n-type impurity concentrations) of the n-type semiconductor regions D1a,S1a may be different from the impurity concentrations (n-type impurity concentrations) of the n-type semiconductor regions D2a,S2a,D3a,S3a. Further, in the ion implantation for forming the n-type semiconductor regions D2a,S2a,D3a,S3a, since the photoresist pattern PR3 can also function as a mask (ion implantation blocking mask), the n-type impurities are not implanted into the semiconductor substrate SB (p-type well PW1) in the MISFET forming region 1A. Thereafter, the photoresist pattern PR3 is removed by ashing or the like.

Next, as shown in FIGS. 16 and 17, the sidewall spacers SW are formed on the sidewalls of the gate electrodes G1,G2,G3. Although not shown here, the sidewall spacers SW are also formed on the sidewalls of the resistive element PS. Subsequent steps are substantially the same as those described with reference to FIGS. 18 to 21, and therefore repeated description thereof will be omitted here. However, ion implantation for forming the n-type semiconductor regions D1b,S1b,D2b,S2b,D3b,S3b is preferable performed in a state where a photoresist pattern is formed so as to cover the resistive element PS in the resistive element forming region 5A and to expose the MISFET forming regions 1A,2A,3A. Accordingly, implantation of the n-type impurities into the resistive element PS can be prevented in the ion implantation step for forming the n-type semiconductor regions D1b,S1b,D2b,S2b,D3b,S3b.

In the manufacturing step of the first modified example, the ion implantation for forming the n-type semiconductor regions D2a,S2a,D3a,S3a of the MISFETs 2,3 having no halo region and the ion implantation for implanting impurities into the resistive element PS are performed by common ion implantation. In the manufacturing step of the first modified example, the photoresist pattern PR2 for preventing the ion implantation into the semiconductor substrate SB in the MISFET forming regions 2A,3A and the photoresist pattern PR2 for preventing the ion implantation into the resistive element PS are common in the ion implantation step for forming the p-type halo regions HA1,HA2 in the MISFET forming region 1A. Therefore, in the manufacturing step of the first modified example, even if the MISFETs 2,3 having no halo regions are not formed, the number of necessary ion implantation steps does not change, and the number of times the photoresist pattern is formed does not change. That is, when the semiconductor device having the MISFET 1 having the halo region and the resistive element PS is manufactured, if the manufacturing step of the first modified example is applied, the MISFETs 2,3 having no halo regions can be formed together without increasing the number of manufacturing steps. Therefore, in the manufacturing step of the first modified example, the semiconductor device having the MISFET 1 having the halo region, the MISFETs 2,3 having no halo regions, and the resistive element PS can be manufactured while suppressing increase in the number of manufacturing steps (thus, while suppressing increase in the manufacturing cost of the semiconductor device).

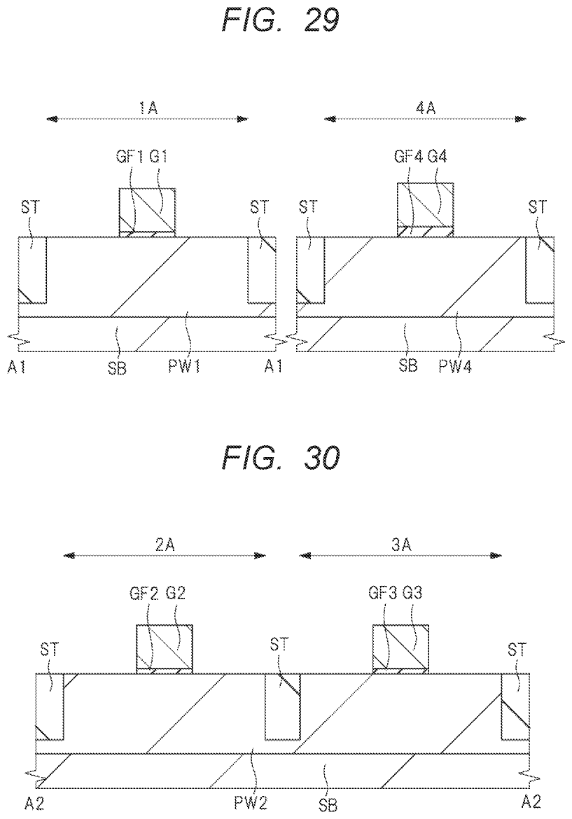

Next, a second modified example of the manufacturing step of the semiconductor device according to the present embodiment will be described with reference to FIG. 29 to FIG. 36. Here, a semiconductor device including the MISFETs 1,2,3 and a high withstand voltage MISFET 4 will be described. Among FIGS. 29 to 36, FIGS. 29, 31, 33, and 35 show cross-sectional views of the MISFET forming region 1A (cross section along A1-A1 line in FIG. 1) on the left side of the drawings, and show cross-sectional views of a high withstand voltage MISFET forming region 4A which is a region (active region) where the high withstand voltage MISFET 4 is formed on the right side of the drawings. Further, among FIGS. 29 to 36, FIGS. 30, 32, 34, and 36 show cross-sectional views (cross section along A2-A2 line in FIG. 4) substantially corresponding to FIG. 5.

FIG. 29 and FIG. 30 show the manufacturing steps corresponding to FIGS. 10 and 11, and show the state where gate electrodes G1,G2,G3,G4 are formed. In the high withstand voltage MISFET forming region 4A, a p-type well PW4 is formed in the semiconductor substrate SB, and the gate electrode G4 is formed on the semiconductor substrate SB (on a p-type well PW4) via a gate dielectric film GF4. The thickness of the gate dielectric film GF4 of the high withstand voltage MISFET 4 is greater than the thickness of each of the gate dielectric films GF1,GF2,GF3 of the MISFETs 1,2,3. Accordingly, the withstand voltage of the MISFET 4 can be made higher than the withstand voltage of each of the MISFETs 1,2,3.

The gate electrode G4 of the high withstand voltage MISFET 4 can be formed in the same step as the gate electrodes G1,G2,G3. Specifically, a dielectric film for the gate dielectric films GF1,GF2,GF3 is formed on the semiconductor substrate SB in the MISFET forming regions 1A,2A,3A and a dielectric film (a dielectric film thicker than the dielectric film for the gate dielectric films GF1,GF2,GF3) for the gate dielectric film GF4 is formed on the semiconductor substrate SB in the high withstand voltage MISFET forming region 4A, and then a conductive film (for example, a polysilicon film) for forming the gate electrodes G1,G2,G3,G4 is formed. Thereafter, the conductive film is patterned using the photolithography method and the dry etching method, whereby the gate electrodes G1,G2,G3,G4 can be formed. Thus, the thickness of the gate dielectric films GF1,GF2,GF3 is the same as one another, but the gate dielectric film GF4 becomes thicker than each of the gate dielectric films GF1,GF2,GF3 of the MISFETs 1,2,3. The thicknesses of the gate electrodes G1,G2,G3,G4 are the same as one another.

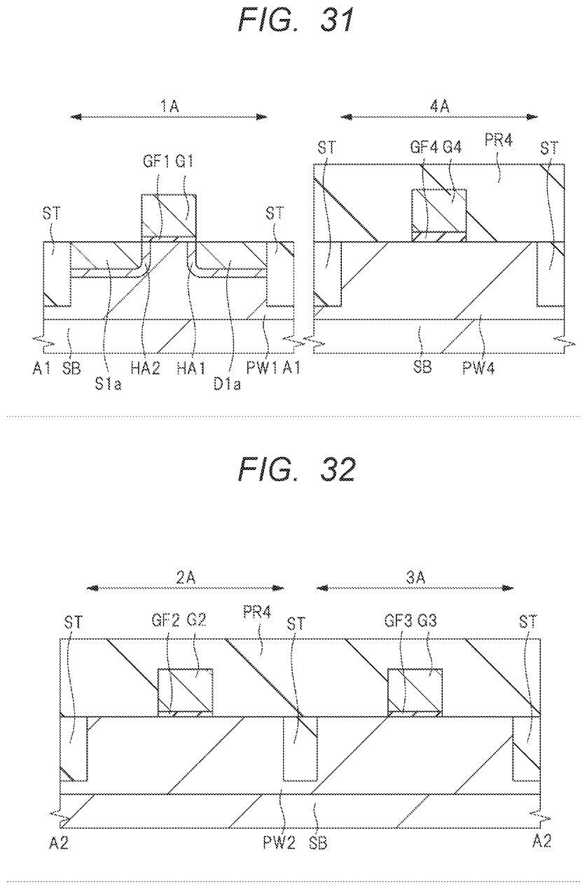

Next, as shown in FIGS. 31 and 32, a photoresist pattern (resist pattern) PR4 is formed on the semiconductor substrate SB using the photolithography technique. The photoresist pattern PR4 is formed to cover the MISFET forming regions 2A,3A,4A and to expose the MISFET forming region 1A. Note that the high withstand voltage MISFET forming region 4A can be regarded as a region in the semiconductor substrate SB in which the high withstand voltage of the MISFET 4 is to be formed.

Next, as shown in FIGS. 31 and 32, the n-type semiconductor regions D1a,S1a are formed in the semiconductor substrate SB (p-type well PW1) in the MISFET forming region 1A by the vertical ion implantation using n-type impurities. In the ion implantation for forming the n-type semiconductor regions D1a,S1a, since the photoresist pattern PR4 can also function as a mask (ion implantation blocking mask), the n-type impurities are not implanted into the semiconductor substrate SB (p-type wells PW2,PW4) in the MISFET forming regions 2A,3A,4A.

Next, as shown in FIGS. 31 and 32, the p-type halo regions HA1,HA2 are formed in the semiconductor substrate SB (p-type well PW1) in the MISFET forming region 1A by the oblique ion implantation using p-type impurities. In the ion implantation for forming the p-type halo regions HA1,HA2, since the photoresist pattern PR4 can also function as a mask (ion implantation blocking mask), the p-type impurities are not implanted into the semiconductor substrate SB (p-type wells PW2,PW4) in the MISFET forming regions 2A,3A,4A.

Note that either of the vertical ion implantation for forming the n-type semiconductor regions D1a,S1a and the oblique ion implantation for forming the p-type halo regions HA1,HA2 may be performed first.

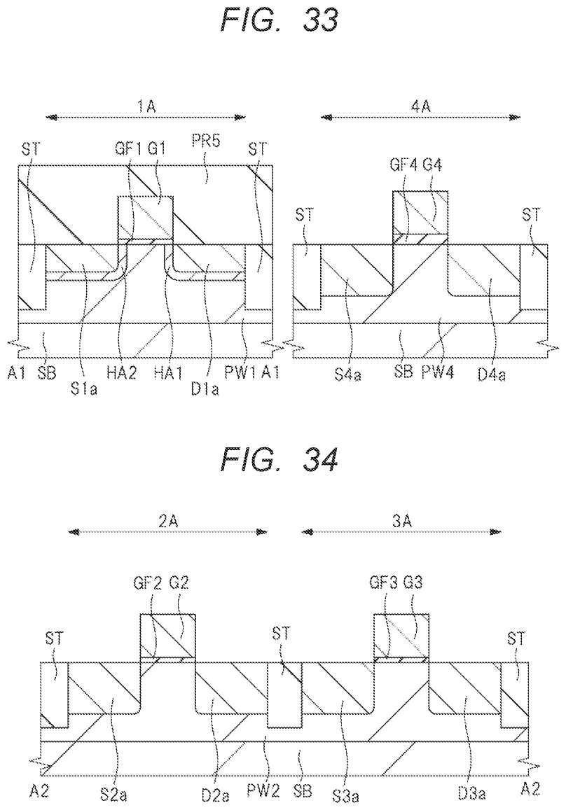

Next, the photoresist pattern PR4 is removed by ashing or the like, and then a photoresist pattern (resist pattern) PR5 is formed on the semiconductor substrate SB using the photolithography technique as shown in FIGS. 33 and 34. The photoresist pattern PR5 is formed to cover the MISFET forming region 1A and to expose the MISFET forming regions 2A,3A,4A.

Next, as shown in FIGS. 33 and 34, n-type semiconductor regions D2a,S2a,D3a,S3a,D4a,S4a are formed in the semiconductor substrate SB (p-type wells PW2,PW4) in the MISFET forming regions 2A,3A,4A by the vertical ion implantation using n-type impurities. The n-type semiconductor regions D4a,S4a are formed on both sides of the gate electrode G4 and in the semiconductor substrate SB (p-type well PW4) in the high withstand voltage MISFET forming region 4A. Since the n-type semiconductor regions D2a,S2a,D3a,S3a,D4a,S4a can be formed by the same ion implantation step, their impurity concentrations (n-type impurity concentrations) are the same as one another. The impurity concentrations (n-type impurity concentrations) of the n-type semiconductor regions D1a,S1a may be different from the impurity concentrations (n-type impurity concentrations) of the n-type semiconductor regions D2a,S2a,D3a,S3a,D4a,S4a. Further, in the ion implantation for forming the n-type semiconductor regions D2a,S2a,D3a,S3a,D4a,S4a, since the photoresist pattern PR5 can also function as a mask (ion implantation blocking mask), the n-type impurities are not implanted into the semiconductor substrate SB (p-type well PW1) in the MISFET forming region 1A. Thereafter, the photoresist pattern PR5 is removed by ashing or the like.

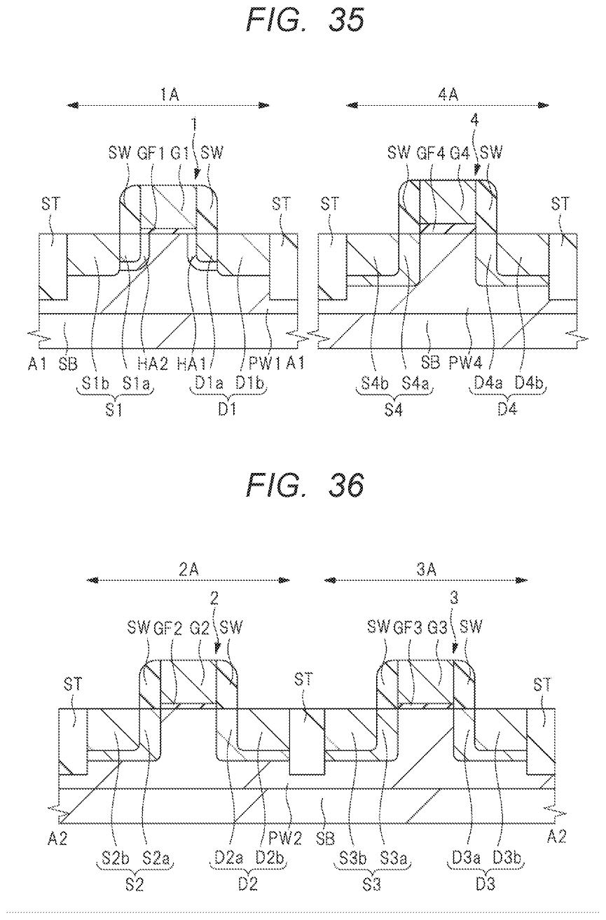

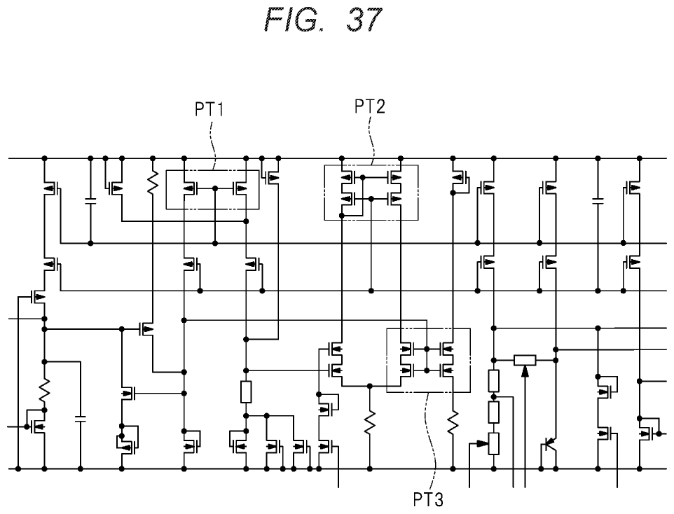

Next, as shown in FIGS. 35 and 36, the sidewall spacers SW are formed on the sidewalls of the gate electrodes G1,G2,G3, G4.

Next, as shown in FIGS. 35 and 36, n-type semiconductor regions D1b,S1b,D2b,S2b,D3b,S3b,D4b,S4b are formed by ion implantation (preferably vertical ion implantation) using n-type impurities. The n-type semiconductor regions D4b,S4b are formed on both sides of the structure formed of the gate electrode G4 and the sidewall spacers SW and in the semiconductor substrate SB (p-type well PW4) in the high withstand voltage MISFET forming region 4A. The n-type impurity concentrations of the n-type semiconductor regions D4b,S4b are higher than the n-type impurity concentrations of the n-type semiconductor regions D4a,S4a. The n-type semiconductor region D4b and the n-type semiconductor region D4a form one of the source/drain regions of the high withstand voltage MISFET 4, and the n-type semiconductor region S4b and the n-type semiconductor region S4a form the other of the source/drain regions of the high withstand voltage MISFET 4. The n-type semiconductor regions D1b,S1b, the n-type semiconductor regions D2b,S2b, the n-type semiconductor regions D3b,S3b, and the n-type semiconductor regions D4b,S4b can be formed by the same ion implantation step, and in such case, their impurity concentrations (n-type impurity concentrations) are the same as one another.

Next, if necessary, activation annealing is performed, which is a heat treatment for activating impurities implanted by ion implantation so far. Subsequent steps are substantially the same as those described with reference to FIGS. 20 and 21, and therefore repeated description thereof will be omitted here.

In the manufacturing step of the second modified example, ion implantation for forming the n-type semiconductor regions D2a,S2a,D3a,S3a of the MISFETs 2,3 having no halo regions and ion implantation for forming the n-type semiconductor regions D4a,S4a of the high withstand voltage MISFET 4 are performed by common ion implantation. In the manufacturing step of the second modified example, the photoresist pattern PR4 for preventing the ion implantation into the semiconductor substrate SB in the MISFET forming region 2A,3A and the photoresist pattern PR4 for preventing the ion implantation into the semiconductor substrate SB in the high withstand voltage MISFET forming region 4A are common in the ion implantation step for forming the p-type halo regions HA1,HA2 in the MISFET forming region 1A. Therefore, in the manufacturing step of the second modified example, even if the MISFETs 2,3 having no halo regions are not formed, the number of necessary ion implantation steps does not change, and the number of times the photoresist pattern is formed does not change. That is, when the semiconductor device having the MISFET 1 having the halo region and the high withstand voltage MISFET 4 is manufactured, if the manufacturing step of the second modified example is applied, the MISFETs 2,3 having no halo regions can be formed together without increasing the number of manufacturing steps. Therefore, in the manufacturing step of the second modified example, the semiconductor device having the MISFET 1 having the halo region, the MISFETs 2,3 having no halo regions, and the high withstand voltage MISFET 4 can be manufactured while suppressing increase in the number of manufacturing steps (thus, while suppressing increase in the manufacturing cost of the semiconductor device).

### Background of Consideration

The present inventors have considered a semiconductor device incorporating an oscillation circuit, and in particular, have considered a microcontroller incorporating the oscillation circuit.

In order to improve the performance of the semiconductor device (in particular, a microcontroller) incorporating the oscillation circuit, increasing the accuracy of the oscillation frequency of the oscillation circuit is necessary. In order to increase the accuracy of the oscillation frequency of the oscillation circuit, increasing the relative accuracy of the pair transistor included in the oscillation circuit is effective.

The pair transistor includes a pair of MISFETs in which the gate electrodes are electrically connected to each other and are formed adjacent to each other on the semiconductor substrate (corresponding to semiconductor substrate SB) configuring the semiconductor device. Since the MISFET 2 and the MISFET 3 shown in FIGS. 4 to 6 are formed adjacent to each other on the semiconductor substrate SB and the gate electrode G2 of the MISFET 2 and the gate electrode G3 of the MISFET 3 are electrically connected to each other via the plug PG and the gate wiring M1G (via the gate connecting portion GC in FIG. 7), the MISFET 2 and the MISFET 3 configure the pair transistor.

FIG. 37 is a circuit diagram showing an example of the oscillation circuit, and shows a part of the oscillation circuit. In the oscillation circuit of FIG. 37, the pair transistor is surrounded by a two-dot chain line. A pair transistor PT1 is configured by two MISFETs (i.e., a pair of MISFETs) of which the gate electrodes are connected to each other. Although the pair transistor PT1 is basic, in the oscillation circuit of FIG. 37, a pair transistor PT2 corresponds to two pair transistors (i.e., two pairs of MISFET), and similarly, a pair transistor PT3 corresponds to two pair transistors (i.e., two pairs of MISFET).

In the pair transistor included in the oscillation circuit, it is required that the electric characteristics (voltage-current characteristics, typically threshold voltages) of the MISFETs configuring the pair transistor match as much as possible. If the electric characteristics (voltage-current characteristics) of the MISFETs configuring the pair transistor included in the oscillation circuit are different from each other, the oscillation frequency of the oscillation circuit may fluctuate. In order to match the oscillation frequency of the oscillation circuit with the designed value, it is effective to match the electric characteristics (voltage-current characteristics) as much as possible between the MISFETs configuring the pair transistor included in the oscillation circuit. That is, it is effective to reduce the difference of the electric characteristics (voltage-current characteristics) between the MISFETs configuring the pair transistor included in the oscillation circuit and to prevent the difference from fluctuating.

Here, the difference (degree of difference) between the electric characteristics (voltage-current characteristics, typically threshold voltages) of the MISFETs configuring the pair transistor is referred to as the relative accuracy of the pair transistor. For this reason, the higher relative accuracy of the pair transistor means a smaller difference of the electric characteristics between the MISFETs configuring the pair transistor. In addition, when the lower relative accuracy of the pair transistor means the large difference of the electric characteristics between the MISFETs configuring the pair transistor. In addition, the relative accuracy of the pair transistor varies means that the difference amounts of the electric characteristics between the MISFET configuring the pair transistor vary for each pair transistor. In addition, the large variation in the relative accuracy of the pair transistor means that the variation in the electric characteristics between the MISFETs configuring the pair transistor varies for each pair transistor, and means that the degree of the variation is large. In addition, suppressing variation in the relative accuracy of the pair transistor means suppressing variation in the electric characteristics of the MISFETs configuring the pair transistor for each pair transistor.

In a semiconductor device (in particular, a microcontroller) incorporating the oscillation circuit, it is necessary to increase the relative accuracy of the pair transistor included in the oscillation circuit and to suppress the variation in the relative accuracy of the pair transistor included in the oscillation circuit, so that it is possible to improve the performance of the semiconductor device (in particular, a microcontroller) incorporating the oscillation circuit by increasing the accuracy of the oscillation frequency of the oscillation circuit.

Meanwhile, the source/drain regions of the MISFET have an LDD structure and include a low concentration region and a high concentration region, and if the halo region (corresponding to the p-type halo region HA1,HA2) having a conductivity type opposite to the low concentration region and being adjacent to the low concentration region is formed, the short-channel effect can be suppressed. For this reason, the MISFET having the halo region is generally applied to the MISFET that configures various types of circuit included in a microcontroller.

However, according to consideration conducted by the present inventors, it has been found out that when the MISFET having the halo region is applied to the MISFET configuring the pair transistor, variations in the relative accuracy of the pair transistor become large. The reason is as follows. That is, when the MISFET having the halo region and the MISFET having no halo region are compared, the MISFET having the halo region has an impurity concentration in the channel forming region higher than the MISFET having no halo region. Further, an unintended variation of the ion implantation conditions or the like may fluctuate the impurity concentration of the channel forming region of the MISFET, and the degree of the variation of the impurity concentration of the channel forming region of the MISFET increases as the impurity concentration of the channel forming region of the MISFET increases. Therefore, compared with the MISFET having no halo region, in the MISFET having the halo region, an unintended variation in the ion implantation conditions and the like is more likely to fluctuate the impurity concentration in the channel forming region of the MISFET, and consequently, the electric characteristics (voltage-current characteristics, typically threshold voltages) of the MISFET are more likely to be varied. As a consequence, when the MISFET having the halo region is applied to the MISFET configuring the pair transistor, the variation in the relative accuracy of the pair transistor increases.

Therefore, it has been found out that, in the semiconductor device (particularly a microcontroller) incorporating the oscillation circuit, when the MISFET having the halo region is applied to the pair transistor included in the oscillation circuit, the variation in the relative accuracy of the pair transistor increases, the accuracy of the oscillation frequency of the oscillation circuit decreases, and the performance of the semiconductor device (particularly a microcontroller) incorporating the oscillation circuit may deteriorate.

Therefore, in order to suppress variation in the relative accuracy of the pair transistor to which the MISFET having the halo region is applied, it is conceivable to increase the planar dimension of the MISFET having the halo region. Increasing the planar dimension (the area of channels) of the MISFET configuring the pair transistor can suppress variations in the relative accuracy of the pair transistor. However, increasing the planar dimension (the area of channels) of the MISFET configuring the pair transistor increases the area of the semiconductor device, which is not a good idea.

### Circuit Configuration of Semiconductor Device

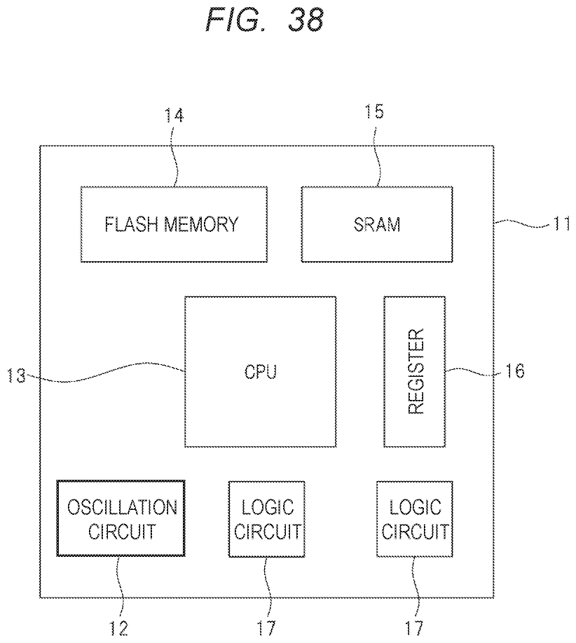

FIG. 38 is a circuit block diagram of the semiconductor device according to the present embodiment. As shown in FIG. 38, a semiconductor device 11 of the present embodiment includes an oscillation circuit 12, and more specifically, is a microcontroller including the oscillation circuit 12. The semiconductor device 11 includes the oscillation circuit 12, a CPU (Central Processing Unit) 13, a flash memory (non-volatile memory) 14, an SRAM (Random Access Memory) 15, a register 16, and a peripheral circuit 17 other than the oscillation circuit. The oscillation circuit 12 is an on-chip oscillation circuit, and specifically, a clock generation circuit. The CPU 13 is configured by a logic circuit. For this reason, the CPU 13 can also be regarded as a logic circuit part. The flash memory 14, the SRAM 15, and the register 16 each function as a storage unit, and thus each can be regarded as a storage circuit.

### Main Features and Effects

As shown in FIGS. 1 to 7, the semiconductor device of the present embodiment includes the semiconductor substrate SB and the MISFETs 1,2,3 formed on the semiconductor substrate SB. Although only one MISFET 1 is shown in FIGS. 1 to 3, a plurality of MISFETs 1 is actually formed on the semiconductor substrate SB. Although only one MISFET 2 and one MISFET 3 are shown in FIGS. 4 to 7, a plurality of MISFETs 2 and a plurality of MISFETs 3 are actually formed on the semiconductor substrate SB. However, the MISFET 2 and the MISFET 3 are electrically connected to each other to form the pair transistor.

The MISFET 1 has the halo regions (corresponding to the p-type halo regions HA1,HA2) as described above, and the MISFETs 2,3 have no halo region as described above.

One of the main features of the present embodiment is that the pair transistor included in the oscillation circuit 12 included in the semiconductor device 11 uses the MISFETs 2,3 having no halo regions instead of the MISFET 1 having the halo region.

As described in the “BACKGROUND OF CONSIDERATION”, unlike the present embodiment, when the MISFET having the halo region is used for the pair transistor included in the oscillation circuit 12, the variation in the relative accuracy of the pair transistor increases, the accuracy of the oscillation frequency of the oscillation circuit decreases, and the performance of the semiconductor device (particularly, the microcontroller) including the oscillation circuit may deteriorate.

On the other hand, in the present embodiment, since the pair transistor included in the oscillation circuit 12 uses the MISFETs 2,3 having no halo regions, rather than the MISFET having the halo region, variation in the relative accuracy of the pair transistor included in the oscillation circuit 12 can be suppressed. The reason is as follows.

That is, when the MISFET having the halo region and the MISFET having no halo region are compared, the MISFET having no halo region is less doped in the channel forming region than in the MISFET having the halo region. Therefore, even if an unintended variation of the ion implantation conditions occurs, the impurity concentration in the channel forming region of the MISFET is less likely to vary in the MISFET having no halo region than in the MISFET having the halo region, and consequently, the electric characteristics (voltage-current characteristics, typically threshold voltages) of the MISFET having no halo region are less likely to vary. As a consequence, when the MISFETs 2,3 having no halo regions are used for the pair transistor included in the oscillation circuit 12, variations in the relative accuracy of the pair transistor included in the oscillation circuit 12 can be suppressed. As a result, the accuracy of the oscillation circuit included in the semiconductor device can be improved, and the performance of the semiconductor device including the oscillation circuit can be improved.

In addition, variation in the relative accuracy of the pair transistor can be suppressed without increasing the planar dimension (channel area) of the MISFET configuring the pair transistor by using the MISFETs 2,3 having no halo region instead of the MISFET having the halo region in the pair transistor in the oscillation circuit 12. Therefore, it is advantageous to reduce the size (area reduction) of the semiconductor device.

Among the various circuits included in the semiconductor device 11, the pair transistor included in the oscillation circuit 12 are required to suppress variations in electric characteristics (voltage-current characteristics, typically threshold voltages) as much as possible. For this reason, the MISFETs 2,3 having no halo regions are used for the pair transistor included in the oscillation circuit 12.

On the other hand, if the MISFET has the halo region, short-channel effect can be suppressed. For this reason, it is preferable to use the MISFET 1 having the halo region in applications where some variation in the electric characteristics is acceptable. For this reason, among the various circuits included in the semiconductor device 11, in the CPU 13, therefore in the logic circuit included in the semiconductor device 11, it is preferable to use the MISFET 1 having the halo region instead of the MISFET 2 or the MISFET 3 having no halo regions. In addition, among the various circuits included in the semiconductor device 11, in the flash memory 14, the SPAM 15, and the register 16, therefore in the storage circuit included in the semiconductor device 11, the MISFET 1 having the halo region is preferably used instead of the MISFET 2 or the MISFET 3 having no halo regions. The flash memory 14 includes a transistor having a storage unit (charge storage unit). Further, in the oscillation circuit 12 included in the semiconductor device 11, it is preferable to use the MISFET 1 having the halo region instead of the MISFET 2 or the MISFET 3 having no halo regions for the MISFET other than the pair transistor. For the peripheral circuit 17 other than the oscillation circuit included in the semiconductor device 11, it is preferable to use the MISFET 1 having the halo region instead of the MISFET 2 or the MISFET 3 having no halo region.

As described above, in the various circuits included in the semiconductor device 11, for applications in which it is required to suppress the variation of the electric characteristics of the MISFET as much as possible, the MISFETs 2,3 having no halo regions are used, and for applications in which some variation of the electric characteristics of the MISFET can be tolerated, the MISFET 1 having the halo region is used. Thus, the performance of the semiconductor device 11 can be improved.

In addition, the semiconductor device 11 has a plurality of MISFETs, and it is preferable that the MISFET having the shortest gate length among the plurality of MISFETs included in the semiconductor device 11 has the halo region as in the MISFET 1. Accordingly, in the MISFET where the influence of the short channel effect is most likely to occur (MISFET of which the gate length is shortest), the short channel effect can be suppressed by forming the halo regions.

As described above, the gate dielectric film GF1 of the MISFET 1, the gate dielectric film GF2 of the MISFET 2 and the gate dielectric film GF3 of the MISFET 3 have the same thickness as one another. On the other hand, the high withstand voltage MISFET 4 (see FIG. 35) described above has the thicker gate dielectric film GF4 than each of the gate dielectric films GF1,GF2,GF3. The thicknesses of the gate dielectric films GF1,GF2,GF3 are the same as one another. The high withstand voltage MISFET 4 does not have halo regions. The high withstand voltage MISFET 4 is preferably used in applications where high withstand voltage is required, and can be used in, for example, the flash memory 14 or the peripheral circuit 17. Therefore, the flash memory 14 and the peripheral circuit 17 may include the MISFET 1 having the thin gate dielectric film GF1 and having the halo region, and the high withstand voltage MISFET 4 having the thick gate dielectric film GF4 and not having the halo region. The CPU 13, the flash memory 14, the SRAM 15, the register 16 and the peripheral circuit 17 (and thus the circuit other than the oscillation circuit 12 included in the semiconductor device 11) preferable do not include the MISFET (corresponding to the MISFET 2 or the MISFET 3) having the gate dielectric film having the same thickness as the gate dielectric film GF1 of the MISFET 1 having no halo region and having no halo region.

Also, the gate dielectric film of each of the MISFETs 1,2,3 is thinner than the gate dielectric film GF4 of the high withstand voltage MISFET 4 and the withstand voltage of each of the MISFETs 1,2,3 is lower than the withstand voltage of the MISFET 4. Therefore, the MISFETs 1,2,3 can be regarded as the low withstand voltage MISFET. In this respect, the technical idea of the present embodiment can also be expressed as follows.

That is, the pair transistor included in the oscillation circuit 12 included in the semiconductor device 11 does not use the MISFET having the halo region, but uses the low withstand voltage MISFET not having the halo region. On the other hand, in the CPU 13 of the semiconductor device 11, it is preferable to use the low withstand voltage MISFET having the halo region without using the low withstand voltage MISFET having no halo region. In addition, in the flash memory 14, the SPAM 15, and the register 16 included in the semiconductor device 11, therefore in the storage circuit of the semiconductor device 11, it is preferable that the low withstand voltage MISFET having the halo region is used without using the low withstand voltage MISFET having no halo region. The flash memory 14 includes a transistor having a storage unit (charge storage unit). In addition, it is preferable that the peripheral circuit 17 other than the oscillation circuit included in the semiconductor device 11 uses the low withstand voltage MISFET having the halo region without using the low withstand voltage MISFET having no halo region. In the peripheral circuit 17 and the storage circuit other than the oscillation circuit included in the semiconductor device 11, in addition to the low withstand voltage MISFET having the halo region, the high withstand voltage MISFET may be used, and the high withstand voltage MISFET may not have the halo region. Therefore, most preferably, in the semiconductor device 11, the pair transistor included in the oscillation circuit 12 uses the low withstand voltage MISFET having no halo region, and the other transistors do not use the low withstand voltage MISFET having no halo region. The low withstand voltage MISFETs have the same thicknesses of the gate dielectric films as each other, and the gate dielectric film of the high withstand voltage MISFET is thicker than the gate dielectric film of the low withstand voltage MISFET.

### Current Direction

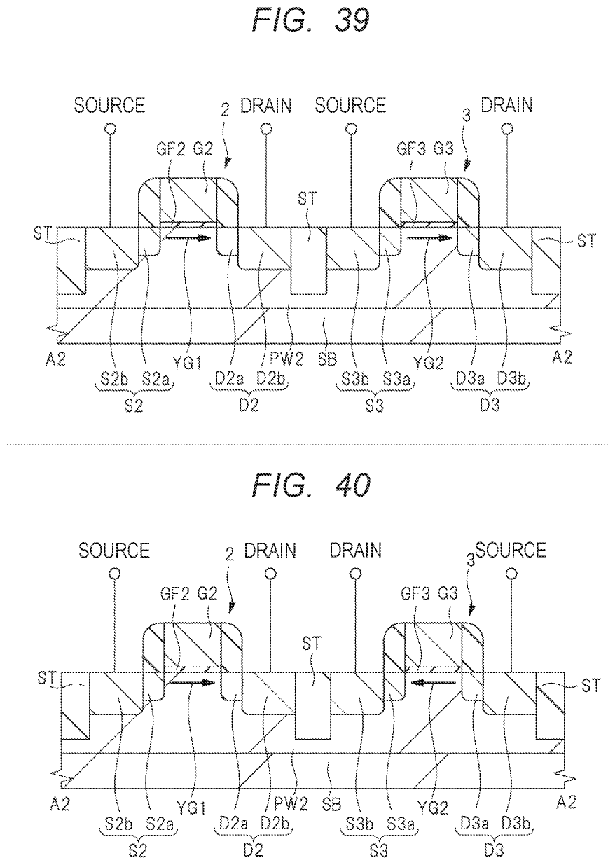

FIG. 39 and FIG. 40 are cross-sectional views of the main portion of the semiconductor device according to the present embodiment and show cross-sections corresponding to FIG. 5. In FIG. 39 and FIG. 40, illustration of the interlayer dielectric film IL, the plug PG, and wiring M1 is omitted for the sake of clarity.

In FIG. 39, the n-type semiconductor region S2 of the MISFET 2 is a source region supplied with a source potential, and the n-type semiconductor region D2 of the MISFET 2 is a drain region supplied with a drain potential. In addition, in FIG. 39, the n-type semiconductor region S3 of the MISFET 3 is a source region supplied with a source potential, and the n-type semiconductor region D3 of the MISFET 3 is a drain region supplied with a drain potential. Therefore, in FIG. 39, the direction YG1 of the current flowing in the MISFET 2 (the direction in which the current flows from the source region to the drain region) and the direction YG2 of the current flowing in the MISFET 3 (the direction in which the current flows from the source region to the drain region) are the same as each other.

On the other hand, in FIG. 40, the n-type semiconductor region S2 of the MISFET 2 is a source region supplied with a source potential, and the n-type semiconductor region D2 of the MISFET 2 is a drain region supplied with a drain potential. In addition, in FIG. 40, the n-type semiconductor region S3 of the MISFET 3 is a drain region supplied with a drain potential, and the n-type semiconductor region D3 of the MISFET 3 is a source region supplied with a source potential. Therefore, in FIG. 40, the direction YG1 of the current flowing in the MISFET 2 (the direction in which the current flows from the source region to the drain region) and the direction YG2 of the current flowing in the MISFET 3 (the direction in which the current flows from the source region to the drain region) are opposite to each other (opposite directions).

It is more preferable when the direction YG1 of the current flowing in the MISFET 2 and the direction YG2 of the current flowing in the MISFET 3 are the same as each other (in the case of FIG. 39) than when the direction YG1 of the current flowing in the MISFET 3 and the direction YG2 of the current flowing in the MISFET 2 are opposite to each other (in the case of FIG. 40). The reason is as follows.

That is, the n-type semiconductor regions D2a,S2a,D3a,S3a and the n-type semiconductor regions D2b,S2b,D3b,S3b are formed by the vertical ion implantation, and the implantation conditions may be unintentionally varied. In order to facilitate the control of the ion implantation step, it is desirable to allow a slight variation in ion implantation conditions (for example, a slight variation in implantation angle). When the direction YG1 of the current flowing in the MISFET 2 and the direction YG2 of the current flowing in the MISFET 3 are the same as each other (in the case of FIG. 39), the variation in the ion implantation conditions (for example, the variation in the implantation angle) is less likely to reduce the relative accuracy of the pair transistor, compared to when the direction YG1 of the current flowing in the MISFET 2 and the direction YG2 of the current flowing in the MISFET 3 are opposite to each other (in the case of FIG. 40).

This is because when the direction YG1 of the current flowing in the MISFET 2 and the direction YG2 of the current flowing in the MISFET 3 are the same as each other, even if the variation of the ion implantation condition (for example, the variation of the implantation angle) occurs, the implantation state of the impurity becomes substantially the same between the source region of the MISFET 2 and the source region of the MISFET 3, and the implantation state of the impurity becomes substantially the same between the drain region of the MISFET 2 and the drain region of the MISFET 3. Therefore, when the direction YG1 of the current flowing in the MISFET 2 and the direction YG2 of the current flowing in the MISFET 3 are the same as each other (in the case of FIG. 39), the relative accuracy of the pair transistor formed of the MISFET 2 and the MISFET 3 can be further improved, compared to when the direction YG1 of the current flowing in the MISFET 2 and the direction YG2 of the current flowing in the MISFET 3 opposite to each other (in the case of FIG. 40).

In the semiconductor substrate SB, it is more preferable that the active region in which the MISFET 2 is formed (MISFET forming region 2A) and the active region in which the MISFET 3 is formed (MISFET forming region 3A) are interposed with the element isolation region ST. More preferably, in the semiconductor substrate SB, the active region in which the MISFET 2 is formed (MISFET forming region 2A) and the active region in which the MISFET 3 is formed (MISFET forming region 3A) are separated by the element isolation region ST. Thus, in the semiconductor substrate SB, the stress generated in the MISFET forming region 2A and the stress generated in the MISFET forming region 3A are easily aligned. Therefore, the relative accuracy of the pair transistor formed of the MISFET 2 and the MISFET 3 can be further improved.

### Test Step and Assembly Step

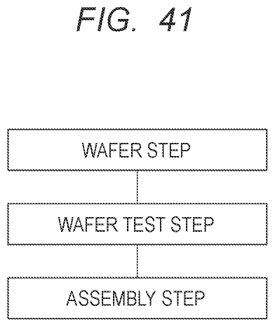

FIG. 41 is a step flow chart showing the manufacturing steps of the semiconductor device. As shown in FIG. 41, the manufacturing steps of the semiconductor device include a wafer step, a wafer test step, and an assembly step in this order. Described above in the “MANUFACTURING STEP OF SEMICONDUCTOR DEVICE” corresponds to the wafer step. The wafer step includes a step of forming a plurality of semiconductor elements including the MISFETs 1,2,3 on the semiconductor wafer (corresponding to semiconductor substrate SB), and a step of forming the wiring structure including the interlayer dielectric film IL, the plug PG, and the wiring M1 on the semiconductor wafer.

In the wafer test step, the semiconductor elements formed on the semiconductor wafer is electrically tested by pressing the test probe on the pad of the wiring structure formed on the semiconductor wafer. In this wafer test step, the electrical test may be performed after the semiconductor wafer is heated to a relatively high temperature (for example, 250° C. or higher). In this case, the heating step is, for example, a retention baking step, and is performed for a relatively long time (for example, about 1 to 10 hours). Further, in the assembly step, the semiconductor wafer is cut by dicing to obtain semiconductor chips, and then the semiconductor chips are used to manufacture semiconductor packages. In this assembly step, the semiconductor chips may be heated to a relatively high temperature (for example, 250° C. or higher). The heating step in this case is, for example, a solder reflow step (more specifically, an infrared-type solder reflow step).

According to consideration by the present inventors, when the MISFET configuring the pair transistor has the halo region, if the semiconductor wafer is heated to a temperature of 250° C. or higher in the wafer test step, or if the semiconductor chip is heated to 250° C. or higher in the assembly step, the impurities included in the halo region are diffused and the relative accuracy of the pair transistor is increased.

In contrast, in the present embodiment, the MISFETs 2,3 configuring the pair transistor do not have the halo region. Therefore, even when the semiconductor wafer is heated to a temperature of 250° C. or higher in the wafer test step (the heating step described above) or when the semiconductor chips are heated to 250° C. or higher in the assembly step (the heating step described above), the decrease of the relative accuracy of the pair transistor formed of the MISFETs 2,3 can be suppressed or prevented. Consequently, the performance of the manufactured semiconductor packages can be improved.

### Pair Transistor

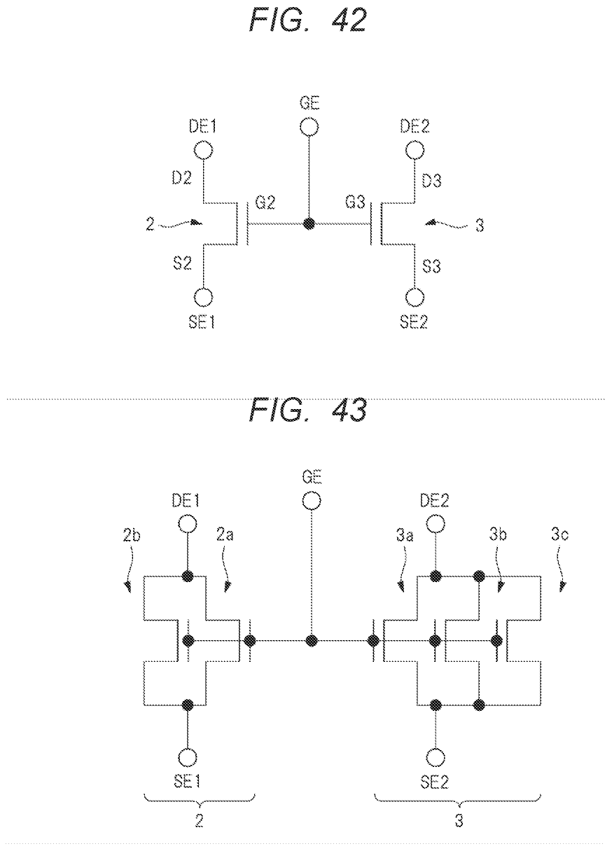

As described above, the pair transistor is formed of a pair of MISFETs formed adjacent to each other on the semiconductor substrate SB and electrically connected to each other. FIG. 42 to FIG. 45 are circuit diagrams showing a circuit example of the pair transistor.

FIG. 42 shows a circuit diagram of a basic form of the pair transistor. In the MISFETs 2,3 configuring the pair transistor, the gate electrode G2 of the MISFET 2 and the gate electrode G3 of the MISFET 3 are electrically connected to each other and connected to a common gate potential GE. The source of the MISFET 2 (n-type semiconductor region S2) is connected to a source potential SE1, the source of the MISFET 3 (n-type semiconductor region S3) is connected to a source potential SE2, the drain of the MISFET 2 (n-type semiconductor region D2) is connected to a drain potential DE1, and the drain of the MISFET 3 (n-type semiconductor region D3) is connected to a drain potential DE2. The connection between the gate electrodes G2,G3 is made through the plug PG and the gate wiring M1G as shown in FIGS. 4 and 6, or through the gate connecting portion GC as shown in FIG. 7.

FIG. 43 shows a schematic diagram of a modified example of the pair transistor. As shown in FIG. 43, one or both of the MISFETs 2,3 configuring the pair transistor may be configured by a plurality of MISFETs connected in parallel. In FIG. 43, for example, the MISFET 2 configuring the pair transistor is configured by two MISFETs 2a,2b connected in parallel, and the MISFET 3 configuring the pair transistor is configured by three MISFETs 3a,3b,3c connected in parallel. The number of parallel connections is not limited to two or three. The MISFETs 2a,2b,3a,3b,3c have no halo regions. Therefore, there may be a case where each of the MISFETs 2,3 configuring the pair transistor is configured by a single MISFET, a case where one of the MISFETs 2,3 configuring the pair transistor is configured by a single MISFET while the other is configured by a plurality of MISFETs connected in parallel, and a case where each of the MISFETs 2,3 configuring the pair transistor is configured by a plurality of MISFETs connected in parallel.

Here, in the plurality of MISFETs connected in parallel, the gate electrodes are electrically connected to each other, the source regions are electrically connected to each other, and the drain regions are electrically connected to each other. The gate electrodes are connected to each other through the plug PG and the gate wiring M1G as shown in FIGS. 4 and 6, or through the gate connecting portion GC as shown in FIG. 7. The source regions can be connected through the plug PG and the wiring M1. The drain regions can be connected through the plug PG and the wiring M1.

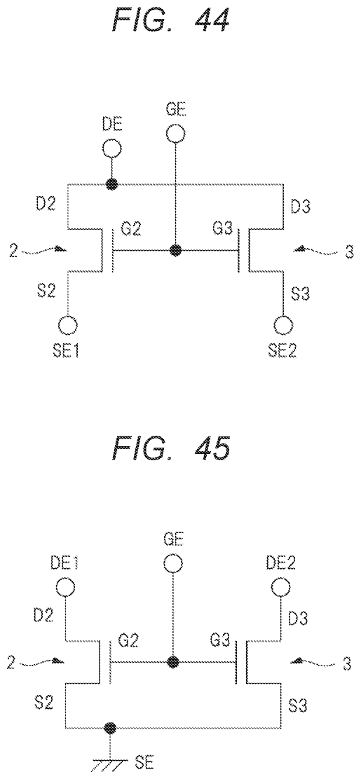

FIG. 44 shows a schematic diagram of another modified example of the pair transistor. As shown in FIG. 44, drains of the MISFETs 2,3 configuring the pair transistor may be electrically connected to each other. That is, in FIG. 44, in the MISFETs 2,3 configuring the pair transistor, the gate electrode G2 of the MISFET 2 and the gate electrode G3 of the MISFET 3 are electrically connected to each other and connected to the common gate potential GE. The drain (n-type semiconductor region D2) of the MISFET 2 and the drain (n-type semiconductor region D3) of the MISFET 3 are electrically connected to each other and connected to a common drain potential DE. The source of the MISFET 2 (n-type semiconductor region S2) is connected to the source potential SE1, and the source of the MISFET 3 (n-type semiconductor region S3) is connected to the source potential SE2. The connection between the gate electrodes G2,G3 is made through the plug PG and the gate wiring M1G as shown in FIGS. 4 and 6, or through the gate connecting portion GC as shown in FIG. 7. The source regions can be connected through the plug PG and the wiring M1.

FIG. 45 shows a schematic diagram of another modified example of the pair transistor. As shown in FIG. 45, the sources of the MISFETs 2,3 configuring the pair transistor may be electrically connected to each other. That is, in FIG. 45, in the MISFETs 2,3 configuring the pair transistor, the gate electrode G2 of the MISFET 2 and the gate electrode G3 of the MISFET 3 are electrically connected to each other and connected to the common gate potential GE. The source of the MISFET 2 (n-type semiconductor region S2) and the source of the MISFET 3 (n-type semiconductor region S3) are electrically connected to each other and connected to a common source potential SE. The drain of the MISFET 2 (n-type semiconductor region D2) is connected to the drain potential DE1, and the drain of the MISFET 3 (n-type semiconductor region D3) is connected to the drain potential DE2. The connection between the gate electrodes G2,G3 is made through the plug PG and the gate wiring M1G as shown in FIGS. 4 and 6, or through the gate connecting portion GC as shown in FIG. 7. The drain regions can be connected through the plug PG and the wiring M1.

Next, a layout example of the pair transistor will be described. FIG. 4 or FIG. 7 above is the basic form of the layout of the pair transistor. In FIG. 4, the MISFET forming region 2A and the MISFET forming region 3A are separated by the element isolation region ST. The MISFET 2 configured by a single MISFET is formed in the MISFET forming region 2A, and the MISFET 3 configured by a single MISFET is formed in the MISFET forming region 3A. The MISFET 2 includes one gate electrode, and the MISFET 3 includes one gate electrode. The gate electrode G2 of the MISFET 2 and the gate electrode G3 of the MISFET 3 are electrically connected to each other to form the pair transistor.

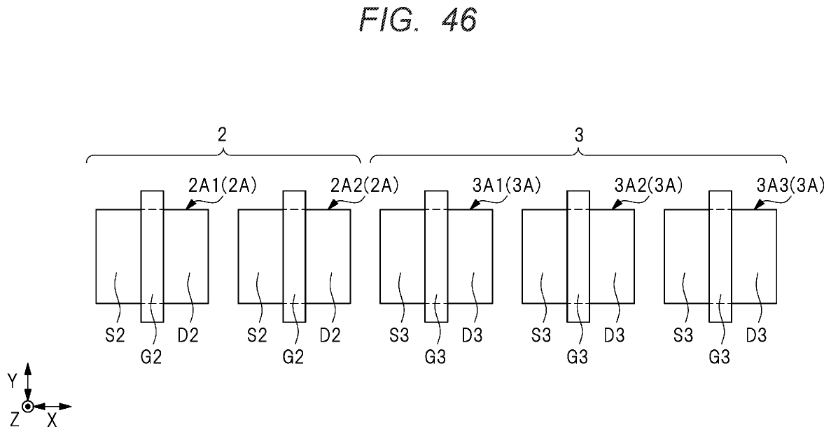

FIG. 46 to FIG. 48 are plan views showing another exemplary layout of the pair transistor.

The layout of FIG. 46 corresponds to the basic form of the layout in the circuit configuration of FIG. 43. Each of the active regions 2A1,2A2,3A1,3A2,3A3 in the semiconductor substrate SB is surrounded by the element isolation region ST in plan view, the MISFET 2a is formed in the active region 2A1, the MISFET 2b is formed in the active region 2A2, the MISFET 3a is formed in the active region 3A1, the MISFET 3b is formed in the active region 3A2, and the MISFET 3c is formed in the active region 3A3. The MISFETs 2a,2b have substantially the same configuration as the MISFET 2 shown in FIGS. 4 to 6 above, and do not have halo regions. Further, the MISFETs 3a,3b,3c have substantially the same configuration as the MISFET 3 shown in FIGS. 4 to 6, and do not have the halo region. The gate electrodes G2 of the MISFETs 2a,2b are electrically connected to each other via the plug PG and the wiring M1, the source regions S2 of the MISFETs 2a,2b are electrically connected to each other via the plug PG and the wiring M1, and the drain regions D2 of the MISFETs 2a,2b are electrically connected to each other via the plug PG and the wiring M1. Further, the gate electrodes G3 of the MISFETs 3a,3b,3c are electrically connected to one another via the plugs PG and the wirings M1, the source regions S3 of the MISFETs 3a,3b,3c are electrically connected to one another via the plugs PG and the wirings M1, and the drain regions D3 of the MISFETs 3a,3b,3c are electrically connected to one another via the plugs PG and the wirings M1. The pair transistor includes the MISFET 2 including the plurality of MISFETs 2a,2b connected in parallel and the MISFET 3 including the plurality of MISFETs 3a,3b,3c connected in parallel.

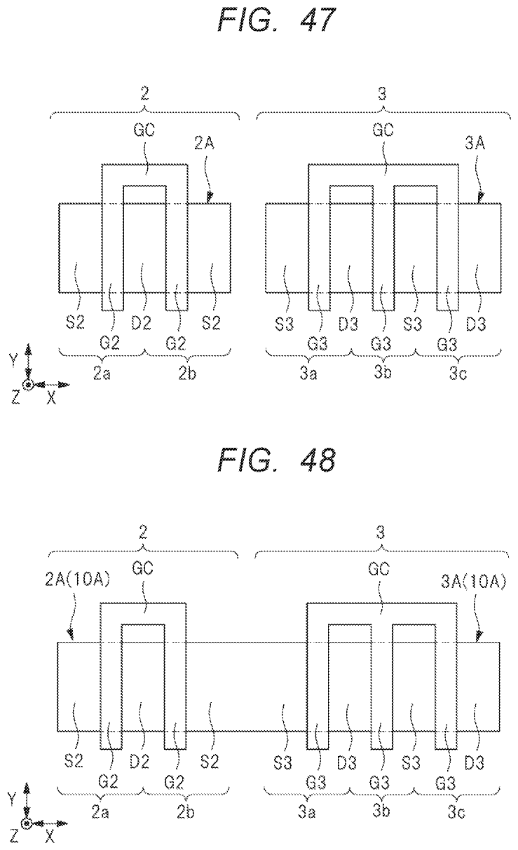

The layout of FIG. 47 corresponds to the modified example of the layout for the circuit configuration of FIG. 43. Each of the MISFET forming regions 2A,3A in the semiconductor substrate SB is surrounded by the element isolation region ST in plan view, the MISFETs 2a,2b are formed in the MISFET forming region 2A, and the MISFETs 3a,3b,3c are formed in the MISFET forming region 3A. The MISFETs 2a,2b have substantially the same structure as the MISFET 2 shown in FIGS. 4 to 6, except that the MISFET 2a and the MISFET 2b share the n-type semiconductor region D2, which is different from the MISFET 2 shown in FIGS. 4 to 6. Further, although the respective MISFETs 3a,3b,3c have the substantially the same structure as the MISFET 3 shown in FIGS. 4 to 6, except that the MISFET 3a and the MISFET 3b share the n-type semiconductor region D3, and the MISFET 3b and the MISFET 3c share the n-type semiconductor region S3, which are different from the MISFET 3 shown in FIGS. 4 to 6.

Therefore, the gate electrode G2 of the MISFET 2a and the gate electrode G2 of the MISFET 2b extend in the Y-direction so as to cross the MISFET forming region 2A, and are arranged in the X-direction. In the MISFET forming region 2A, the n-type semiconductor region S2 and the n-type semiconductor region D2 are alternately arranged in the X-direction with the gate electrode G2 interposed therebetween. The gate electrodes G2 of the MISFETs 2a,2b are electrically connected to each other via the plug PG and the wiring M1. The source regions of the MISFETs 2a,2b (here, the n-type semiconductor regions S2) are electrically connected to each other via the plug PG and the wiring M1. In addition, the drain regions of the MISFETs 2a,2b (here, the n-type semiconductor region D2) are electrically connected to each other by being shared. In the MISFET forming region 2A, no halo region is formed.

The gate electrodes G3 of the MISFET 3a, the gate electrode G3 of the MISFET 3b and the gate electrode G3 of the MISFET 3c extend in the Y-direction so as to cross the MISFET forming region 3A, respectively, and are arranged in the X-direction. In the MISFET forming region 3A, the n-type semiconductor region S3 and the n-type semiconductor region D3 are alternately arranged in the X-direction with the gate electrode G3 interposed therebetween. The gate electrodes G3 of the MISFETs 3a,3b,3c are electrically connected to each other via the plug PG and the wiring M1. The source regions of the MISFETs 3a,3b,3c (here, the n-type semiconductor regions S2) are electrically connected to each other via the plug PG and the wiring M1. Also, the drain regions of the MISFETs 3a,3b,3c (here, the n-type semiconductor regions D2) are electrically connected to each other via the plug PG and the wiring M1. In the MISFET forming region 3A, no halo region is formed.

In FIG. 47, the pair transistor includes the MISFET 2 formed of the plurality of MISFETs 2a,2b (MISFETs not having the halo region) formed in the MISFET forming region 2A and connected in parallel, and the MISFET 3 formed of the plurality of MISFETs 3a, 3b, 3c (MISFETs not having the halo region) formed in the MISFET forming region 3A and connected in parallel.

Note that, in FIG. 47, the gate electrodes G2 are formed in the MISFET forming region 2A, and the gate electrodes G3 are formed in the MISFET forming region 3A. The number of gate electrodes G2 is the same as the number of MISFETs configuring the MISFET 2 (MISFETs connected in parallel). The number of gate electrodes G3 is the same as the number of MISFETs configuring the MISFET 3 (MISFETs connected in parallel).

The layout of FIG. 48 corresponds to the modified example of the layout for the circuit configuration of FIG. 43. In FIG. 48, the element isolation region ST is not interposed between the MISFET forming region 2A and the MISFET forming region 3A in the semiconductor substrate SB, and the MISFET forming region 2A and the MISFET forming region 3A are connected. Here, the entire active region including the MISFET forming region 2A and the MISFET forming region 3A is referred to as the MISFET forming region 10A. The MISFET forming region 10A is surrounded by the element isolation region ST in plan view. Then, among the MISFET forming region 10A, the MISFET forming region 2A is formed with the MISFETs 2a,2b, and the MISFET forming region 3A is formed with the MISFETs 3a,3b,3c. Since the structure of FIG. 48 is basically the same as the structure of FIG. 47 except that the element isolation region ST is not interposed between the MISFET forming region 2A and the MISFET forming region 3A, repetitive explanation thereof will be omitted here.

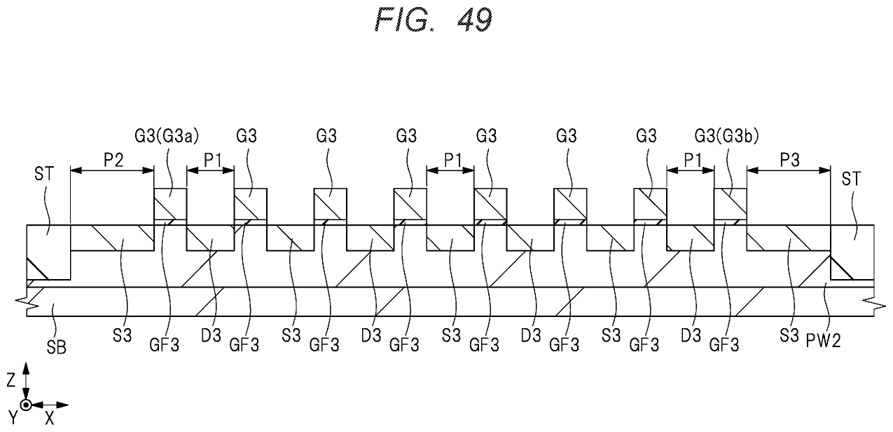

FIG. 49 is a schematic cross-sectional view of the semiconductor device when the layout of FIG. 47 is applied. FIG. 49 shows a cross-sectional view (a cross-sectional view substantially orthogonal to the Y-direction) of the MISFET forming region 3A when the MISFET 3 configuring the pair transistor is configured by a plurality of MISFETs connected in parallel. Hereinafter, the gate electrodes G3 in the MISFET forming region 3A will be described with reference to FIG. 49. The same technical idea holds for the gate electrode G2 in the MISFET forming region 2A, and in FIG. 49 and the following explanation, the “MISFET forming region 3A” may be read as the “MISFET forming region 2A”, the “gate electrode G3” may be read as the “gate electrode G2”, the “n-type semiconductor region S3” may be read as the “n-type semiconductor region S2”, and the “n-type semiconductor region D3” may be read as the “n-type semiconductor region D2”.

In FIG. 49, since the MISFET 3 configuring the pair transistor is configured by the plurality of MISFETs connected in parallel, the plurality of gate electrodes G3 extend in the Y-direction so as to cross the MISFET forming regions 3A, and are arranged in the X-direction. In the MISFET forming region 3A, the n-type semiconductor region S3 and the n-type semiconductor region D3 are alternately arranged in the X-direction with the gate electrode G3 interposed therebetween. In FIG. 49, the number of the gate electrodes G3 is eight, but is not limited to eight.

In FIG. 49, the distance P1 between the gate electrodes G3 adjacent to each other in the X-direction is constant. That is, the plurality of gate electrodes G3 extending in the Y-direction are arranged in the X-direction at predetermined distance P1. Here, one of the gate electrodes G3 located at both ends in the X-direction among the plurality of gate electrodes G3 arranged in the X-direction is referred to as the gate electrode G3a, and the other is referred to as the gate electrode G3b. The distance (distance in the X-direction) P2 between the gate electrode G3a and the element isolation region ST is preferably larger than the distance P1 (i.e., P2>P1). In addition, the distance (distance in the X-direction) P3 between the gate electrode G3b and the element isolation region ST is preferably larger than the distance P1 (i.e., P3>P1). The reason is as follows.

In the active region (MISFET forming region 3A), the regions adjacent to the element isolation region ST are more likely to fluctuate in the distribution of impurities than in the other regions. Therefore, when the MISFET 3 formed of the plurality of MISFETs connected in parallel is formed, the electric characteristics of the MISFET having the gate electrode G3a and the MISFET having the gate electrode G3b may be fluctuated compared with other MISFET.

Therefore, as shown in FIG. 49, the distances P2,P3 between the gate electrodes G3a,G3b and the element isolation region ST located at both ends in the X-direction, among the plurality of gate electrodes G3 formed in the MISFET forming regions 3A, is set to be larger than the distance P1 between the adjacent gate electrodes G3 (P2>P1 and P3>P1). Accordingly, since the gate electrodes G3a,G3b are far from the element isolation region ST, even if the distribution of impurities fluctuates in a region close to the element isolation region ST in the active region (MISFET forming region 3A), the influence of fluctuation on the electric characteristics of the MISFET having the gate electrode G3a and the MISFET having the gate electrode G3b can be suppressed. Accordingly, the fluctuation of the electric characteristics of the MISFET 3 can be suppressed or prevented more accurately when the MISFET 3 configuring the pair transistor is configured by the plurality of MISFETs connected in parallel. The same technical idea holds for the gate electrodes G2 in the MISFET forming region 2A, and when the MISFET 2 configuring the pair transistor is configured by the plurality of MISFETs connected in parallel, the fluctuation of the electric characteristics of the transistor can be suppressed or prevented more accurately. As a result, variations in the relative accuracy of the pair transistor formed of the MISFETs 2,3 can be suppressed.

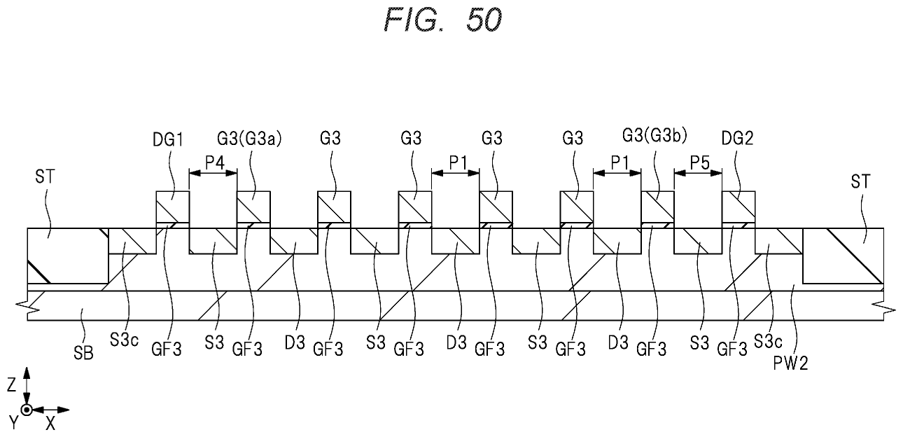

FIG. 50 is a schematic cross-sectional view of the semiconductor device when the layout of FIG. 47 is applied. FIG. 50 shows a cross-sectional view (a cross-sectional view substantially orthogonal to the Y-direction) of the MISFET forming region 3A when the MISFET 3 configuring the pair transistor is configured by the plurality of MISFETs connected in parallel, and shows a cross section corresponding to FIG. 49. Hereinafter, the gate electrodes G3 in the MISFET forming region 3A will be described with reference to FIG. 50. The same technical idea holds for the gate electrodes G2 in the MISFET forming region 2A, and in FIG. 50 and the following explanation, the “MISFET forming region 3A” may be read as the “MISFET forming region 2A”, the “gate electrode G3” may be read as the “gate electrode G2”, the “n-type semiconductor region S3” may be read as the “n-type semiconductor region S2”, and the “n-type semiconductor region D3” may be read as the “n-type semiconductor region D2”.

In FIG. 50, since the MISFET 3 configuring the pair transistor is configured by the plurality of MISFETs connected in parallel, the plurality of gate electrodes G3 extends in the Y-direction so as to cross the MISFET forming regions 3A, and is arranged in the X-direction. In the MISFET forming region 3A, the n-type semiconductor region S3 and the n-type semiconductor region D3 are alternately arranged in the X-direction with the gate electrode G3 interposed therebetween.

In FIG. 50, the number of the gate electrode G3 is six, but the number is not limited to six.

In FIG. 50, the distance P1 between the gate electrodes G3 adjacent to each other in the X-direction is constant. That is, the plurality of gate electrodes G3 extending in the Y-direction is arranged in the X-direction at a predetermined distance P1. Dummy gate electrodes DG1,DG2 are disposed on both sides (both sides in the X-direction) of the plurality of gate electrodes G3 arranged in the X-direction. That is, the dummy gate electrode DG1 is disposed on one of both sides (both sides in the X-direction) of the plurality of gate electrodes G3 arranged in the X-direction, and the dummy gate electrode DG2 is disposed on the other side. The dummy gate electrodes DG1,DG2 extend in the Y-direction. In other words, the dummy electrode DG1 extending in the Y-direction is disposed between the gate electrode G3a and the element isolation region ST, among the plurality of gate electrodes G3 arranged in the X-direction, and the dummy electrode DG2 extending in the Y-direction is disposed between the gate electrode G3b and the element isolation region ST, among the plurality of gate electrodes G3 arranged in the X-direction. As described above, the gate electrodes G3a,G3b are located at both ends in the X-direction among the plurality of gate electrodes G3 arranged in the X-direction. The distance P4 between the gate electrode G3a and the adjacent dummy electrode DG1 and the distance P5 between the gate electrode G3b and the adjacent dummy electrode DG2 may be the same as the distance P1 between the adjacent gate electrodes G3 in the X-direction (i.e., P1=P4=P5).

The dummy gate electrodes DG1,DG2 are pseudo gate electrodes and do not function as the gate electrode of the transistor. The dummy gate electrodes DG1,DG2 are not connected to the gate electrode G3 through the conductor, and the gate voltage applied to the gate electrode G3 is not applied to the dummy gate electrodes DG1,DG2. Since the dummy gate electrodes DG1,DG2 are formed in the same step as the gate electrode G3, the dummy gate electrodes DG1,DG2 are formed of the same material (for example, polysilicon) as the gate electrode G3 and has the same thickness as the gate electrode G3. Similar to the gate electrode G3, the dummy gate electrodes DG1,DG2 also extend in the Y-direction so as to cross the MISFET forming region 3A. In the semiconductor substrate SB (p-type well PW2), the n-type semiconductor region S3c is formed between each of the dummy gate electrodes DG1,DG2 and the element isolation region ST. The n-type semiconductor region S3c is formed together when the n-type semiconductor region D3,S3 is formed in the semiconductor substrate SB. The n-type semiconductor region S3c does not function as a source/drain region of the transistor.

Therefore, the dummy gate electrodes DG1,DG2 and the plurality of gate electrodes G3 extending in the Y-direction are arranged in the X-direction, the dummy gate electrodes DG1,DG2 are disposed at both ends of the arrangement in the X-direction, and the plurality of gate electrodes G3 extending in the Y-direction are disposed between the dummy gate electrode DG1 extending in the Y-direction and the dummy gate electrode DG2 extending in the Y-direction. Therefore, the dummy gate electrodes DG1,DG2 are adjacent to the element isolation region ST in the X-direction (that is, closest to the element isolation region ST in the X-direction) instead of the gate electrodes G3. The reason why the dummy electrodes DG1,DG2 are preferable provided is as follows.

That is, as described above, in the active region (MISFET forming region 3A), the regions adjacent to the element isolation region ST are more likely to fluctuate as compared with the regions other than the regions. Therefore, when the MISFET 3 formed of the plurality of MISFETs connected in parallel is formed in the MISFET forming region 3A, the electric characteristics of the MISFET having the gate electrode G3a and the MISFET having the gate electrode G3b among the plurality of MISFETs may fluctuate, compared with other MISFET.

Therefore, as shown in FIG. 50, the dummy electrodes DG1,DG2 are formed on both sides of the plurality of gate electrodes G3 formed in the MISFET forming region 3A. Thus, in the X-direction, the dummy electrodes DG1,DG2 are formed between the gate electrode G3 and the element isolation region ST, and therefore, even if the distribution of impurities fluctuates in a region close to the element isolation region ST in the active region (MISFET forming region 3A), the influence of the fluctuation on the MISFET having the gate electrode G3 can be suppressed or prevented.

Accordingly, when the MISFET 3 configuring the pair transistor is configured by the plurality of MISFETs connected in parallel, the fluctuation in the electric characteristics of the MISFET 3 can be suppressed or prevented more accurately. The same technical idea holds for the gate electrode G2 in the MISFET forming region 2A, and when the MISFET 2 configuring the pair transistor is configured by the plurality of MISFETs 2 connected in parallel, the fluctuation in the electric characteristics of the MISFET 2 can be suppressed or prevented more accurately. As a result, variations in the relative accuracy of the pair transistor formed of the MISFETs 2,3 can be suppressed.

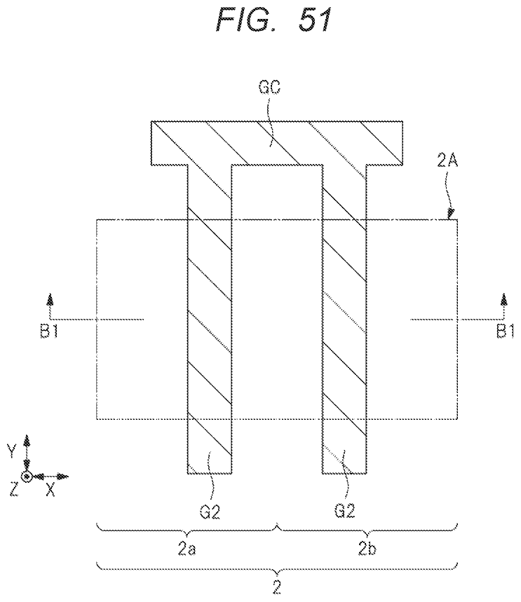

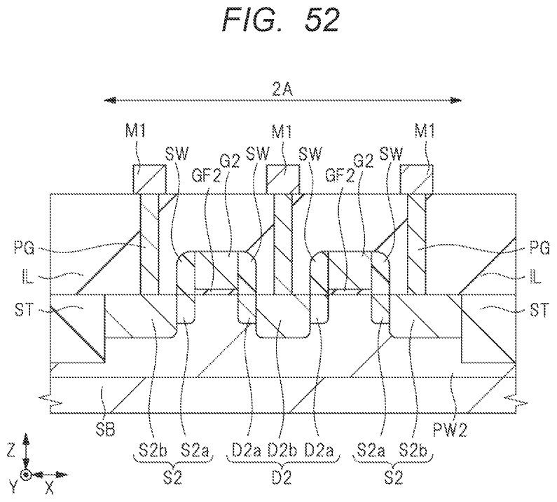

FIG. 51 and FIG. 52 are main portion plan view (FIG. 51) and main portion cross-sectional view (FIG. 52) of the semiconductor device showing the layout of the MISFET forming region 2A of FIG. 47. FIG. 51 shows a plan view of the MISFET forming region 2A, and cross-sectional view along B1-B1 line in FIG. 51 corresponds to FIG. 52.

The layout of FIG. 51 corresponds to the layout of the MISFET forming region 2A of FIG. 47. Therefore, in FIG. 51 and FIG. 52, the MISFET forming region 2A of the semiconductor substrate SB is surrounded by the element isolation region ST in plan view, and the MISFETs 2a,2b is formed in the MISFET forming region 2A. The gate electrode G2 of the MISFET 2a and the gate electrode G2 of the MISFET 2b extend in the Y-direction so as to cross the MISFET forming region 2A, and are arranged in the X-direction. In FIG. 51, the gate electrode G2 of the MISFET 2a and the gate electrode G2 of the MISFET 2b are integrally connected to the gate connecting portion GC extending in the X-direction, and are electrically connected to each other through the gate connecting portion GC. The sidewall spacers SW are formed on the sidewalls of the gate electrode G2 and the sidewalls of the gate connecting portion GC. In the MISFET forming region 2A, the n-type semiconductor region S2 and the n-type semiconductor region D2 are alternately arranged in the X-direction with the gate electrode G2 interposed therebetween. The MISFET 2a and the MISFET 2b share the n-type semiconductor regions D2. In the MISFET forming region 2A, no halo region is formed in the semiconductor substrate SB.

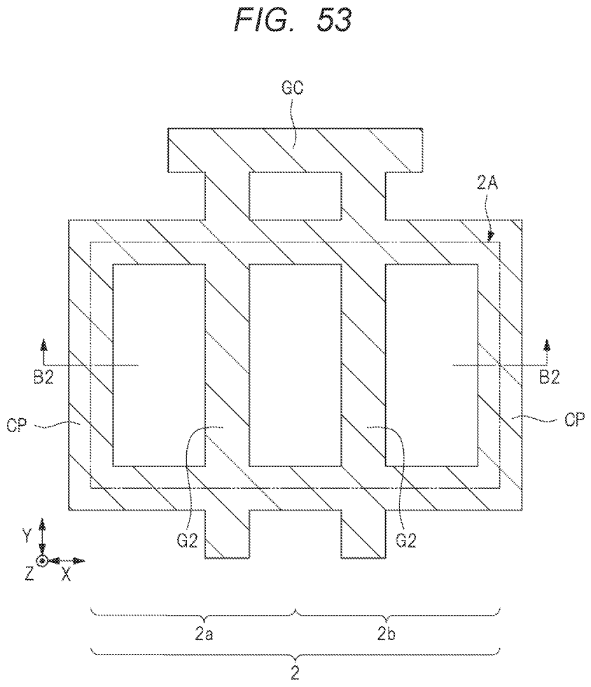

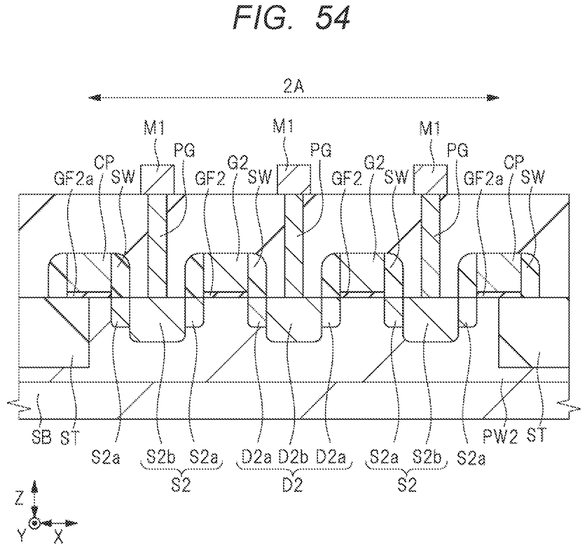

FIG. 53 and FIG. 54 are main portion plan view (FIG. 53) and main portion cross-sectional view (FIG. 54) of the semiconductor device showing modified example for the structures of FIGS. 51 and 52 above. FIG. 53 shows plan view of the MISFET forming region 2A, and cross-sectional view along B2-B2 line in FIG. 53 corresponds to FIG. 54.

The structures of FIGS. 53 and 54 differ from the structures of FIGS. 51 and 52 as follows.

That is, the gate electrode G2 extends in the Y-direction so as to cross the MISFET forming region 2A, but in the cases of FIGS. 53 and 54, a conductive portion CP extending on the semiconductor substrate SB along the outer periphery of the MISFET forming region 2A (active region) (that is, along the boundary between the element isolation region ST and the active region) is integrally connected to the gate electrode G2. Since the conductive portion CP is formed in the same step as the gate electrode G2, the conductive portion CP is formed of the same material (for example, polysilicon) as the gate electrode G2, has the same thickness as the gate electrode G2, and is formed integrally with the gate electrode G2. Since the conductive portion CP is formed integrally with the gate electrode G2, the conductive portion CP does not function as the gate electrode of the transistor, although the gate voltage applied to the gate electrode G2 can also be applied to the conductive portion CP. The conductive portion CP extends along the outer periphery of the MISFET forming region 2A while overlapping with both the element isolation region ST and the active region (MISFET forming region 2A). The sidewall spacers SW are formed on the sidewalls of the gate electrode G2, the sidewalls of the gate connecting portion GC, and the sidewalls of the conductive portion CP. The dielectric film GF2a having the same layer as that of the gate dielectric film GF2 is interposed between the conductive portion CP and the semiconductor substrate SB (p-type well PW2). In the ion implantation step of forming the n-type semiconductor regions D2a,S2a and the ion implantation step of forming the n-type semiconductor regions D2b,S2b, the n-type impurities are not implanted into the region under the gate electrode G2 and the region under the conductive portion CP in the semiconductor substrate SB (p-type well PW2). Therefore, the n-type semiconductor regions D2a,S2a and the n-type semiconductor regions D2b,S2b are not formed in the region under the conductive portion CP in the semiconductor substrate SB (p-type well PW2).

In the cases of FIGS. 53 and 54, the conductive portion CP extends along the outer periphery of the MISFET forming region 2A, and the n-type semiconductor regions D2,S2 are not formed in the region under the conductive portion CP. Therefore, in the active region (MISFET forming region 2A), the n-type semiconducting regions D2,S2 are not formed in the region adjacent to the element isolation region ST. When the conductive portion CP is formed as shown in FIGS. 53 and 54, the following advantages can be obtained.

In other words, in the active region (MISFET forming region 2A), the region adjacent to the element isolation region ST is more likely to fluctuate in the distribution of impurities than in the other regions. However, when the conductive portion CP is formed as shown in FIGS. 53 and 54, the n-type semiconductor regions D2,S2 are not formed in the region adjacent to the element isolation region ST in the active region (MISFET forming region 2A). Accordingly, the variation in the distribution of impurities in the active region (MISFET forming region G2) in the region adjacent to the element isolation region ST can be suppressed or prevented from affecting the MISFET having the gate electrode G2.

Accordingly, the fluctuation in the electric characteristics of the MISFET 2 configuring the pair transistor can be suppressed or prevented more accurately. The same technical idea holds for the gate electrode G3 in the MISFET forming region 3A, and the fluctuation in the electric characteristics of the MISFET 3 can be suppressed or prevented more accurately. As a result, variations in the relative accuracy of the pair transistor formed of the MISFETs 2,3 can be suppressed.

On the other hand, when the conductive portion CP is not formed as shown in FIGS. 51 and 52, the size (area) of the semiconductor device can be reduced by not forming the conductive portion CP as compared with the cases shown in FIGS. 53 and 54.

As for the MISFET 1 formed in the MISFET forming region 1A, it is preferable to apply a configuration in which the conductive portion CP is not formed as shown in FIGS. 51 and 52. This is because, compared to the MISFETs 2,3, the MISFET 1 can tolerate some variation in the electric characteristics and therefore applies a structure with halo regions. This makes it possible to reduce the size (area) of the semiconductor device.

The invention made by the present inventor has been described above in detail based on the embodiment, but the present invention is not limited to the embodiment described above, and it is needless to say that various modifications can be made without departing from the gist thereof.

What is claimed is:

1. A semiconductor device including an oscillation circuit, comprising:
a semiconductor substrate;
a plurality of first MISFETs formed on the semiconductor substrate; and
a plurality of second MISFETs formed on the semiconductor substrate,
wherein each of the plurality of first MISFETs includes:
a first semiconductor region formed in the semiconductor substrate and acting as a source or a drain;
a first gate electrode formed on the semiconductor substrate via a first gate dielectric film; and
a first halo region of a conductivity type opposite to a conductivity type of the first semiconductor region, the first halo region formed in the semiconductor substrate so as to be adjacent to the first semiconductor region,
wherein each of the plurality of second MISFETs includes:
a second semiconductor region formed in the semiconductor substrate and acting as a source or a drain; and
a second gate electrode formed on the semiconductor substrate via a second gate dielectric film,
wherein the each of the plurality of second MISFETs does not include a halo region of the conductivity type opposite to the conductivity type of the first semiconductor region in a position adjacent to the second semiconductor region in the semiconductor substrate, and
wherein the plurality of second MISFETs is used as a pair transistor included in the oscillation circuit.

2. The semiconductor device according to claim 1, comprising:
a logic circuit,
wherein the plurality of first MISFETs is used as the logic circuit.

3. The semiconductor device according to claim 1,
wherein the plurality of first MISFETs is used as a MISFET other than the pair transistor included in the oscillation circuit.

4. The semiconductor device according to claim 1, comprising:
a memory circuit,
wherein the plurality of first MISFETs is used as the memory circuit.

5. The semiconductor device according to claim 1, comprising:
a logic circuit; and
a memory circuit,
wherein the plurality of first MISFETs is used as a MISFET other than the pair transistor included in the oscillation circuit, the logic circuit, and the memory circuit.

6. The semiconductor device according to claim 1,
wherein the first gate dielectric film included in the each of the plurality of first MISFETs has the same thickness as a thickness of the second gate dielectric film included in the plurality of second MISFETs.

7. The semiconductor device according to claim 1,
wherein the first semiconductor region includes:
a first low concentration region; and
a first high concentration region having the same conductivity type as a conductivity type of the first low concentration region and having an impurity concentration higher than an impurity concentration of the first low concentration region,
wherein the second semiconductor region includes:
a second low concentration region; and
a second high concentration region having the same conductivity type as a conductivity type of the second low concentration region and having an impurity concentration higher than an impurity concentration of the second low concentration region, and
wherein the first halo region is formed in a position adjacent to the first low concentration region.

8. A semiconductor device including an oscillation circuit, comprising:
a semiconductor substrate; and
a first MISFET used as a pair transistor included in the oscillation circuit; and
a second MISFET used as the pair transistor included in the oscillation circuit,
wherein the first MISFET includes:
a first semiconductor region of a first conductivity type formed in the semiconductor substrate and acting as a source or a drain; and
at least one first gate electrode formed on the semiconductor substrate via a first gate dielectric film,
wherein the second MISFET includes:
a second semiconductor region of the first conductivity type formed in the semiconductor substrate and acting as a source or a drain; and
a second gate electrode formed on the semiconductor substrate via a second gate dielectric film,
wherein the first MISFET does not include a halo region of a second conductivity type opposite to the first conductivity type in a position adjacent to the first semiconductor region in the semiconductor substrate,
wherein the second MISFET does not include a halo region of the second conductivity type in a position adjacent to the second semiconductor region in the semiconductor substrate, and
wherein the at least one first gate electrode and the second gate electrode are electrically connected to each other.

9. The semiconductor device according to claim 8, comprising:
a third MISFET used as a logic circuit,
wherein the third MISFET includes:
a third semiconductor region of the first conductivity type formed in the semiconductor substrate and acting as a source or a drain;
a third gate electrode formed on the semiconductor substrate via a third gate dielectric film, and
a first halo region of the second conductivity type formed in the semiconductor substrate so as to be adjacent to the third semiconductor region,
wherein a thickness of the first gate dielectric film, a thickness of the second gate dielectric film, and a thickness of the third gate dielectric film are the same as each other.

10. The semiconductor device according to claim 8, comprising:
an element isolation region formed in the semiconductor substrate,
wherein the first semiconductor region is formed in a first active region surrounded by the element isolation region in the semiconductor substrate,
wherein the second semiconductor region is formed in a second active region surrounded by the element isolation region in the semiconductor substrate,
wherein the at least one first gate electrode extends so as to be across the first active region in plan view, and
wherein the second gate electrode extends so as to be across the second active region in plan view.

11. The semiconductor device according to claim 10,
wherein a direction of current flowing in the semiconductor substrate by the first MISFET is the same as a direction of current flowing in the semiconductor substrate by the second MISFET.

12. The semiconductor device according to claim 10,
wherein a first conductor portion extending on the semiconductor substrate so as to be along an outer periphery of the first active region is integrally formed with the first gate electrode.

13. The semiconductor device according to claim 10,
wherein the at least one first gate electrode includes a plurality of first gate electrodes, and
wherein the plurality of first gate electrodes is electrically connected to each other.

14. The semiconductor device according to claim 13,
wherein each of the plurality of first gate electrodes extends in a first direction and arranged in a second direction orthogonal to the first direction,
wherein a plurality of first distances between the plurality of first gate electrodes is the same as each other,
wherein a second distance between the element isolation region and one of two, among the plurality of first gate electrodes arranged in the second direction, located at both ends in the second direction is greater than each of the plurality of first distances, and
wherein a third direction between the element isolation region and another one of the two, among the plurality of first gate electrodes arranged in the second direction, located at the both ends in the second direction is greater than the each of the plurality of first distances.

15. The semiconductor device according to claim 13,
wherein each of the plurality of first gate electrodes extends in a first direction and arranged in a second direction orthogonal to the first direction,
wherein a first dummy electrode extending in the first direction is disposed between the element isolation region and one of two, among the plurality of first gate electrodes arranged in the second direction, located at both ends in the second direction, and
wherein a second dummy electrode extending in the first direction is disposed between the element isolation region and another one of the two, among the plurality of first gate electrodes arranged in the second direction, located at the both ends in the second direction.

16. A method of manufacturing a semiconductor device including an oscillation circuit, the method comprising:
(a) preparing a semiconductor substrate;
(b) forming a first gate electrode of a first MISFET on the semiconductor substrate via a first gate dielectric film, forming a second gate electrode of a second MISFET on the semiconductor substrate via a second gate dielectric film, and forming a third gate electrode of a third MISFET on the semiconductor substrate via a third gate dielectric film;
(c) after the (b), forming a first semiconductor region of a first conductivity type acting as a source or a drain of the first MISFET in the semiconductor substrate, forming a first halo region of a second conductivity type opposite to the first conductivity type adjacent to the first semiconductor region in the semiconductor substrate, forming a second semiconductor region of the first conductivity type acting as a source or a drain of the second MISFET in the semiconductor substrate, and forming a third semiconductor region of the first conductivity type acting as a source or a drain of the third MISFET in the semiconductor substrate;
(d) after the (c), forming an interlayer dielectric film on the semiconductor substrate so as to cover the first gate electrode, the second gate electrode and the third gate electrode;
(e) after the (d), forming a conductive plug buried in the interlayer dielectric film; and
(f) after the (e), forming a wiring on the interlayer dielectric film,
wherein in the (c), a halo region of the second conductivity type is not formed in a position adjacent to the second semiconductor region in the semiconductor substrate, and the halo region of the second conductivity type is not formed in a position adjacent to the third semiconductor region in the semiconductor substrate,
wherein the second gate electrode and the third gate electrode are electrically connected to each other, and
wherein the second MISFET and the third MISFET are used as a pair transistor included in the oscillation circuit.

17. The method according to claim 16,
wherein the first MISFET is used as a logic circuit.

18. The method according to claim 16,
wherein the (c) includes:
(c1) forming a first low concentration region of the first conductivity type, a second low concentration region of the first conductivity type and a third low concentration region of the first conductivity type in the semiconductor substrate by first vertical ion implantation;
(c2) after the (c1), forming a first resist pattern, the first resist pattern covering a region in the semiconductor substrate where the second MISFET is to be formed and a region in the semiconductor substrate where the third MISFET is to be formed and exposing a region in the semiconductor substrate where the first MISFET is to be formed;
(c3) after the (c2), forming the first halo region of the second conductivity type in the semiconductor substrate so as to be adjacent to the first low concentration region by an oblique ion implantation;
(c4) after the (c3), removing the first resist pattern;
(c5) after the (c4), forming a sidewall spacer on each of sidewalls of the first gate electrode, the second gate electrode and the third gate electrode; and
(c6) after the (c5), forming a first high concentration region of the first conductivity type, a second high concentration region of the first conductivity type and a third high concentration region of the first conductivity type in the semiconductor substrate by a second vertical ion implantation,
wherein the first high concentration region has an impurity concentration higher than an impurity concentration of the first low concentration region,
wherein the second high concentration region has an impurity concentration higher than an impurity concentration of the second low concentration region,
wherein the third high concentration region has an impurity concentration higher than an impurity concentration of the third low concentration region,
wherein the first semiconductor region is formed of the first low concentration region and the first high concentration region,
wherein the second semiconductor region is formed of the second low concentration region and the second high concentration region, and
wherein the third semiconductor region is formed of the third low concentration region and the third high concentration region.

19. The method according to claim 16,
wherein the semiconductor substrate prepared in the (a) includes an element isolation region,
wherein in the (b), a resistive element formed of the same material of the first gate electrode, the second gate electrode and the third gate electrode on the element isolation region,
wherein the (c) includes;
(c1) forming a first resist pattern, the first resist pattern covering a region in the semiconductor substrate where the second MISFET is to be formed, a region in the semiconductor substrate where the third MISFET is to be formed and the resistive element and exposing a region in the semiconductor substrate where the first MISFET is to be formed;
(c2) after the (c1), forming a first low concentration region of the first conductivity type in the semiconductor substrate by a first vertical ion implantation;
(c3) after the (c1), forming the first halo region of the second conductivity type in the semiconductor substrate by an oblique ion implantation;
(c4) after the (c2) and the (c3), removing the first resist pattern;
(c5) after the (c4), forming a second resist pattern, the second resist pattern covering the region in the semiconductor substrate where the first MISFET is to be formed and exposing the region in the semiconductor substrate where the second MISFET is to be formed, the region in the semiconductor substrate where the third MISFET is to be formed and the resistive element;
(c6) after the (c5), forming a second low concentration region of the first conductivity type and a third low concentration region of the first conductivity type in the semiconductor substrate by a second vertical ion implantation;
(c7) after the (c6), removing the second resist pattern;
(c8) after the (c7), forming a sidewall spacer on each of sidewalls of the first gate electrode, the second gate electrode and the third gate electrode; and
(c9) after the (c8), forming a first high concentration region of the first conductivity type, a second high concentration region of the first conductivity type and a third high concentration region of the first conductivity type in the semiconductor substrate by a third vertical ion implantation,
wherein the first high concentration region has an impurity concentration higher than an impurity concentration of the first low concentration region,
wherein the second high concentration region has an impurity concentration higher than an impurity concentration of the second low concentration region,
wherein the third high concentration region has an impurity concentration higher than an impurity concentration of the third low concentration region,
wherein the first semiconductor region is formed of the first low concentration region and the first high concentration region,
wherein the second semiconductor region is formed of the second low concentration region and the second high concentration region,
wherein the third semiconductor region is formed of the third low concentration region and the third high concentration region, and
wherein in the (c6), an impurity of the second conductivity type is implanted into the resistive element by the second vertical ion implantation.

20. The method according to claim 16,
wherein in the (b), a fourth gate electrode of a fourth MISFET is formed on the semiconductor substrate via a fourth gate dielectric film,
wherein the fourth gate dielectric film is thicker than each of the first gate dielectric film, the second gate dielectric film and the third gate dielectric film,
wherein the (c) includes:
(c1) forming a first resist pattern, the first resist pattern covering a region in the semiconductor substrate where the second MISFET is to be formed, a region in the semiconductor substrate where the third MISFET is to be formed and a region in the semiconductor substrate where the fourth MISFET is to be formed and exposing a region in the semiconductor substrate where the first MISFET is to be formed;
(c2) after the (c1), forming a first low concentration region of the first conductivity type in the semiconductor substrate by a first vertical ion implantation;
(c3) after the (c1), forming the first halo region of the second conductivity type in the semiconductor substrate by an oblique ion implantation;
(c4) after the (c2) and the (c3), removing the first resist pattern;
(c5) after the (c4), forming a second resist pattern, the second resist pattern covering the region in the semiconductor substrate where the first MISFET is to be formed and exposing the region in the semiconductor substrate where the second MISFET is to be formed, the region in the semiconductor substrate where the third MISFET is to be formed and the region in the semiconductor substrate where the fourth MISFET is to be formed;
(c6) after the (c5), forming a second low concentration region of the first conductivity type, a third low concentration region of the first conductivity type and a fourth low concentration region of the first conductivity type in the semiconductor substrate by a second vertical ion implantation;
(c7) after the (c6), removing the second resist pattern;
(c8) after the (c7), forming a sidewall spacer on each of sidewalls of the first gate electrode, the second gate electrode, the third gate electrode and the fourth gate electrode; and
(c9) after the (c8), forming a first high concentration region of the first conductivity type, a second high concentration region of the first conductivity type, a third high concentration region of the first conductivity type and a fourth high concentration region of the first conductivity type in the semiconductor substrate by a third vertical ion implantation,
wherein the first high concentration region has an impurity concentration higher than an impurity concentration of the first low concentration region,
wherein the second high concentration region has an impurity concentration higher than an impurity concentration of the second low concentration region,
wherein the third high concentration region has an impurity concentration higher than an impurity concentration of the third low concentration region,
wherein the fourth high concentration region has an impurity concentration higher than an impurity concentration of the fourth low concentration region,
wherein the first semiconductor region is formed of the first low concentration region and the first high concentration region,
wherein the second semiconductor region is formed of the second low concentration region and the second high concentration region,
wherein the third semiconductor region is formed of the third low concentration region and the third high concentration region, and
wherein a fourth semiconductor region of the first conductivity type acting as a source or a drain of the fourth MISFET is formed of the fourth low concentration region and the fourth high concentration region.
